(19) United States
(12) Patent Application Publication
(10) Pub. No.: US 2026/0291517 A1
(43) Pub. Date: Sep. 24, 2026

(54) VECTOR COMPRESSION BASED ON SATISFYING A METRIC

(71) Applicant: Lenovo (Singapore) Pte. Limited, Singapore (SG)

(72) Inventors: Venkata Srinivas Kothapalli, Aurora, IL (US); Vijay Nangia, Woodridge, IL (US); Vahid Pourahmadi, München (DE); Ahmed Hindy, Aurora, IL (US)

(73) Assignee: Lenovo (Singapore) Pte. Limited, Singapore (SG)

(21) Appl. No.: 19/469,058

(22) PCT Filed: Mar. 22, 2024
(86) PCT No.: PCT/IB2024/052783

§ 371 Date: Sep. 25, 2025

Related U.S. Application Data
(60) Provisional application No. 63/492,401, filed on Mar. 27, 2023.

(51) Int. Cl. H03M 7/30; H04B 7/06; H04L 5/00; H04L 25/02; H04L 69/04

(52) U.S. Cl. CPC H03M 7/3082; H04B 7/0626; H04L 5/0048; H04L 69/04; H04L 25/0254

(57) ABSTRACT

Various aspects of the present disclosure relate to vector compression based on satisfying a metric. At one wireless device (e.g., a user equipment) an information vector having unit Euclidean length is factorized into two or more factor vectors based on Khatri-Rao factorization. Each of the two or more factor vectors has fewer elements than the information vector, and the total number of elements in the two or more factor vectors is less than the number of elements in the information vector. The two or more factor vectors are encoded and transmitted to another wireless device (e.g., a network entity).

### RELATED APPLICATION

This application claims priority to U.S. Patent Application Ser. No. 63/492,401 filed Mar. 27, 2023 entitled “VECTOR COMPRESSION BASED ON SATISFYING A METRIC,” the disclosure of which is incorporated by reference herein in its entirety.

### TECHNICAL FIELD

The present disclosure relates to wireless communications, and more specifically to compressing vectors.

### BACKGROUND

A wireless communications system may include one or multiple network communication devices, such as base stations, which may be otherwise known as an eNodeB (eNB), a next-generation NodeB (gNB), or other suitable terminology. Each network communication devices, such as a base station may support wireless communications for one or multiple user communication devices, which may be otherwise known as user equipment (UE), or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., sixth generation (6G)).

In the wireless communications system, data can be transmitted from one device to another, such as from a UE to a base station (e.g., a gNB) or from a base station (e.g., a gNB) to a UE. Various data can be transmitted, such as channel state information (CSI), data to be used with artificial intelligence or machine learning (AI/ML) models, and so forth.

### SUMMARY

The present disclosure relates to methods, apparatuses, and systems that support vector compression based on satisfying a metric. At one wireless device (e.g., a UE) an information vector having unit Euclidean length (a Euclidean length of 1) is factorized into two or more factor vectors based on Khatri-Rao (KR) factorization. Each of the two or more factor vectors has fewer elements than the information vector, and the total number of elements in the two or more factor vectors is less than the number of elements in the information vector. The two or more factor vectors are encoded and transmitted to another wireless device (e.g., a network entity). By factoring the information vector, overhead is reduced in the wireless communications system due to the first factor vector and the second factor vector together being smaller than the information vector.

Some implementations of the method and apparatuses described herein may further include to: factorize, based on Khatri-Rao factorization and so that a metric is satisfied, at least one information vector into one or more components wherein each component comprises of a first factor vector and a second factor vector, and each of the first factor vector and the second factor vector has fewer elements than the information vector, and the at least one information vector has unit Euclidean length and includes a set of information parameters; generate encoded information by encoding at least the first factor vector or the second factor vector in at least one of the components; and transmit, to a first device, a first signaling indicating the encoded information.

In some implementations of the method and apparatuses described herein, the first factor vector is a first column vector, the second factor vector is a second column vector, and the information vector is a column vector. Additionally or alternatively, the set of information parameters are based on channel state information. Additionally or alternatively, the method and apparatuses are to receive, from the first device, at least one reference signal; and generate channel state information based on the received at least one reference signal. Additionally or alternatively, the channel state information comprises a characterization of a channel matrix that includes at least one of one or more singular vectors of the channel matrix, one or more eigen vectors of the channel matrix, one or more eigen vectors of a channel covariance matrix, or one or more precoding vectors. Additionally or alternatively, the method and apparatuses are to determine the information parameters of the set of information parameters are based on distinct attributes extracted by an artificial intelligence or machine learning model. Additionally or alternatively, the method and apparatuses are to determine the information parameters of the set of information parameters based on signaling from a second device that is different than the first device. Additionally or alternatively, the method and apparatuses are to map the information vector to obtain a real-valued information vector using a mapping that is a one-to-one mapping known at the first device. Additionally or alternatively, to generate the encoded information is to determine at least one quantized representation of at least the first factor vector or the second factor vector in at least one of the one or more components based on at least one of a scalar quantization or a vector quantization scheme. Additionally or alternatively, to generate the encoded information is to encode at least the first factor vector or the second factor vector in at least one of the one or more components in a form of at least one index corresponding to one or more codebooks. Additionally or alternatively, the one or more codebooks correspond to at least one of a spatial transformation, a frequency transformation, and a time domain transformation. Additionally or alternatively, to generate the encoded information is to obtain a latent representation of at least the first factor vector or the second factor vector in at least one of the one or more components using an artificial intelligence or machine learning model. Additionally or alternatively, to generate the encoded information is to bit encode at least the first factor vector or the second factor vector in at least one of the one or more components. Additionally or alternatively, the method and apparatuses are to determine a number of components into which the information vector is factorized. Additionally or alternatively, the method and apparatuses are to transmit, to the first device, a second signaling indicating a number of components into which the information vector is factorized. Additionally or alternatively, the method and apparatuses are to receive, from the first device or a second device other than the first device, a second signaling; and determine, based on the second signaling, a number of components into which the information vector is factorized. Additionally or alternatively, the method and apparatuses are to determine a length of the first factor vector and the second factor vector in each of the one or more components. Additionally or alternatively, the method and apparatuses are to transmit, to the first device, a second signaling indicating a length of the first factor vector and the second factor vector in each of the one or more components. Additionally or alternatively, the method and apparatuses are to receive, from the first device or a second device other than the first device, a second signaling indicating a length of the first factor vector and the second factor vector in each of the one or more components. Additionally or alternatively, the method and apparatuses are to determine the one or more components based on an error threshold. Additionally or alternatively, the method and apparatuses are to determine an error threshold based on a message signal received from the first device or a second device other than the first device; and determine the one or more components based on the received error threshold. Additionally or alternatively, the method and apparatuses are to factorize, based on Khatri-Rao factorization, the first factor vector into one or more additional components that each include a third factor vector and a fourth factor vector; and generate the encoded information by encoding at least the third factor vector or the fourth factor vector in at least one of the one or more additional components. Additionally or alternatively, the method and apparatuses are to determine an error vector indicating an error between the at least one information vector and a Khatri-Rao product of the first factor vector and the second factor vector; select a particular number of largest elements of the error vector; and include, in the first signaling, an indication of both the particular number of largest elements of the error vector and positions of the particular number of largest elements in the error vector. Additionally or alternatively, a number of the one or more components is greater than one and a length of the first factor vector in a first component of the one or more components is different from the length of the first factor vector in a second component of the one or more components, and wherein the method and apparatuses are to cause the apparatus to perform a factorization process to determine the first factor vector and the second factor vector in a particular component by: dividing the information vector into a first number of vectors each having a first length, wherein the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; multiplying the first factor vector with the highest singular value or multiplying the second factor vector with the highest singular value, or multiplying the first factor vector and the second factor vector each with a square root of the highest singular value; computing an error vector by subtracting a column-wise Khatri-Rao product of the first factor vector of the first component with the second factor vector of the first component from the information vector; computing a value of a function of the error vector to determine an error value; stopping the factorization process if the error value is less than an error threshold or a number of components have been computed; and replacing, if the error value is greater than the error threshold or if less than the number of components have been computed, the information vector with the error vector and repeating the factorization process. Additionally or alternatively, the first factor vector has a same dimension in each of the one or more components, the second factor vector has a same dimension in each of the one or more components, and the method and apparatuses are to determine, for each component, the first factor vector and the second factor vector by: dividing the information vector into a first number of vectors each having a first length wherein the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; and multiplying the first factor vector in the first component with the highest singular value or multiplying the second factor vector in the first component with the highest singular value or multiplying the first factor vector and the second factor vector each, in the first component, with a square root of the highest singular value. Additionally or alternatively, a number of components and lengths of factor vectors in each of the one or more components are determined by a machine learning model. Additionally or alternatively, the metric is cosine similarity or cosine distance.

Some implementations of the method and apparatuses described herein may further include to: receive, from a first device, a first signaling indicating a set of information and a set of parameters, wherein the set of information comprises at least one set of components wherein each component includes an encoded first factor vector and an encoded second factor vector and wherein each set of components corresponds to an information vector; decode the encoded first factor vector and the encoded second factor vector; generate a Khatri-Rao product of the first factor vector and the second factor vector corresponding to each of the components; and reconstruct an information vector by adding the Khatri-Rao products corresponding to each of the components.

In some implementations of the method and apparatuses described herein, the set of parameters comprises one or more of information indicating a number of components of at least one set of components, or dimensions of the encoded first and second factor vectors in each component of at least one set of components, and wherein encoding performed at the first device includes at least one of a quantization codebook associated with at least one vector dequantization or de-mapping scheme. Additionally or alternatively, the method and apparatuses are to determine the first set of parameters based on one or more of a predefined value or an indication received from the first device or a different device than the first device. Additionally or alternatively, the first factor vector is a first column vector, the second factor vector is a second column vector, and the information vector is a column vector. Additionally or alternatively, the method and apparatuses are to decode at least the first factor vector or the second factor vector in at least one of the components from at least one index corresponding to one or more codebooks. Additionally or alternatively, the one or more codebooks correspond to at least one of a spatial transformation, a frequency transformation, and a time domain transformation. Additionally or alternatively, the method and apparatuses are to decode at least the first factor vector or the second factor vector in at least one of the components from a latent representation received using an artificial intelligence of a machine learning model. Additionally or alternatively, the method and apparatuses are to transmit, to the first device, a second signaling indicating a number of components into which the information vector is to be factorized. Additionally or alternatively, the method and apparatuses are to transmit, to the first device, a second signaling indicating a length of the first factor vector and the second factor vector in each of the components.

### BRIEF DESCRIPTION OF THE DRAWINGS

FIG. 1 illustrates an example of a wireless communications system that supports vector compression based on satisfying a metric in accordance with aspects of the present disclosure.

FIG. 2 illustrates an example of providing CSI feedback using vector compression based on satisfying a metric in accordance with aspects of the present disclosure.

FIG. 3 illustrates an example of providing data using vector compression based on satisfying a metric in accordance with aspects of the present disclosure.

FIGS. 4 and 5 illustrate examples of block diagrams of devices that support vector compression based on satisfying a metric in accordance with aspects of the present disclosure.

FIGS. 6 through 10 illustrate flowcharts of methods that support vector compression based on satisfying a metric in accordance with aspects of the present disclosure.

### DETAILED DESCRIPTION

Vectors including various information can be transmitted from one device to another in a wireless communications system (e.g., from a network entity to a UE or from a UE to a network entity). The vectors can be used in various scenarios, such as where the vectors are used for beamforming or precoding over multiple input multiple output (MIMO) wireless channels or where the vectors include distinct attributes (of, for example, a document or an image) and are used as inputs to an AI/ML model for inference (e.g., prediction or classification). The transfer of these vectors in a wireless communications system consumes bandwidth in the wireless communications system, and in some situations transferring these vectors is considered overhead in the wireless communications system because it is not user data.

The techniques discussed herein describe a lossy compression method for compressing a vector having unit Euclidean length (also referred to as unit norm). A given unit norm vector is factorized into a product of two or more factor vectors having smaller dimensions than the original vector using Khatri-Rao Factorization (KRF) or, equivalently, column-wise Kronecker Product Decomposition (KPD). The vector reconstructed from its factor vectors will have a higher cosine similarity, or equivalently, smaller cosine distance, from the original vector. Reference is made herein to using the techniques for singular vectors or eigen vectors of a wireless channel matrix, the techniques discussed herein are equally applicable to any vector having unit norm.

The factor vectors are smaller than the original vector so transmitting the factor vectors to a receiving device (e.g. a network entity or a UE) rather than the original vector reduces the amount of data transmitted (as well as stored). For example, the UE transmits fewer data values to the network entity than would be transmitted for the original vector, but the network entity can use these fewer data values to reconstruct the original vector. Although using the factor vectors may result in loss of some quality or accuracy in the data values transmitted, the original vector can still be reconstructed well enough and having sufficient quality to allow the transmitting device (e.g., the network entity for downlink) to use the reconstructed vector as if the original vector had not been factored into the factor vectors.

Aspects of the present disclosure are described in the context of a wireless communications system. Aspects of the present disclosure are further illustrated and described with reference to device diagrams and flowcharts.

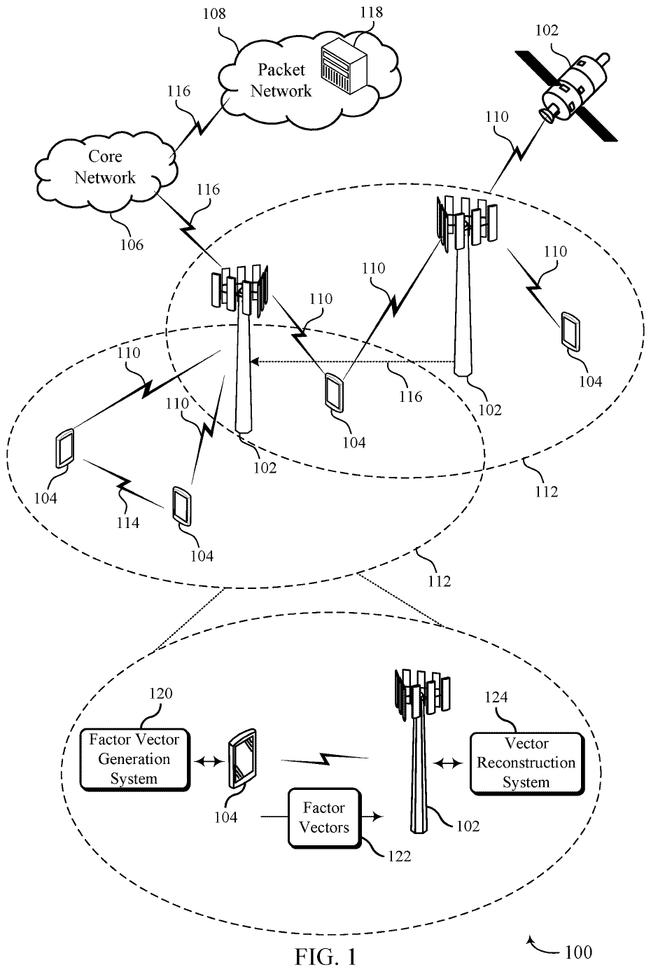

FIG. 1 illustrates an example of a wireless communications system 100 that supports vector compression based on satisfying a metric in accordance with aspects of the present disclosure. The wireless communications system 100 may include one or more network entities 102, one or more UEs 104, a core network 106, and a packet data network 108. The wireless communications system 100 may support various radio access technologies. In some implementations, the wireless communications system 100 may be a 4G network, such as an LTE network or an LTE-Advanced (LTE-A) network. In some other implementations, the wireless communications system 100 may be a 5G network, such as an NR network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G. Additionally, the wireless communications system 100 may support technologies, such as time division multiple access (TDMA), frequency division multiple access (FDMA), or code division multiple access (CDMA), etc.

The one or more network entities 102 may be dispersed throughout a geographic region to form the wireless communications system 100. One or more of the network entities 102 described herein may be or include or may be referred to as a network node, a base station, a network element, a radio access network (RAN), a base transceiver station, an access point, a NodeB, an eNodeB (eNB), a next-generation NodeB (gNB), or other suitable terminology. A network entity 102 and a UE 104 may communicate via a communication link 110, which may be a wireless or wired connection. For example, a network entity 102 and a UE 104 may perform wireless communication (e.g., receive signaling, transmit signaling) over a Uu interface.

A network entity 102 may provide a geographic coverage area 112 for which the network entity 102 may support services (e.g., voice, video, packet data, messaging, broadcast, etc.) for one or more UEs 104 within the geographic coverage area 112. For example, a network entity 102 and a UE 104 may support wireless communication of signals related to services (e.g., voice, video, packet data, messaging, broadcast, etc.) according to one or multiple radio access technologies. In some implementations, a network entity 102 may be moveable, for example, a satellite associated with a non-terrestrial network. In some implementations, different geographic coverage areas 112 associated with the same or different radio access technologies may overlap, but the different geographic coverage areas 112 may be associated with different network entities 102. Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The one or more UEs 104 may be dispersed throughout a geographic region of the wireless communications system 100. A UE 104 may include or may be referred to as a mobile device, a wireless device, a remote device, a remote unit, a handheld device, or a subscriber device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples. In some implementations, a UE 104 may be stationary in the wireless communications system 100. In some other implementations, a UE 104 may be mobile in the wireless communications system 100.

The one or more UEs 104 may be devices in different forms or having different capabilities. Some examples of UEs 104 are illustrated in FIG. 1. A UE 104 may be capable of communicating with various types of devices, such as the network entities 102, other UEs 104, or network equipment (e.g., the core network 106, the packet data network 108, a relay device, an integrated access and backhaul (IAB) node, or another network equipment), as shown in FIG. 1. Additionally, or alternatively, a UE 104 may support communication with other network entities 102 or UEs 104, which may act as relays in the wireless communications system 100.

A UE 104 may also be able to support wireless communication directly with other UEs 104 over a communication link 114. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link 114 may be referred to as a sidelink. For example, a UE 104 may support wireless communication directly with another UE 104 over a PC5 interface.

A network entity 102 may support communications with the core network 106, or with another network entity 102, or both. For example, a network entity 102 may interface with the core network 106 through one or more backhaul links 116 (e.g., via an S1, N2, N6, or another network interface). The network entities 102 may communicate with each other over the backhaul links 116 (e.g., via an X2, Xn, or another network interface). In some implementations, the network entities 102 may communicate with each other directly (e.g., between the network entities 102). In some other implementations, the network entities 102 may communicate with each other or indirectly (e.g., via the core network 106). In some implementations, one or more network entities 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

In some implementations, a network entity 102 may be configured in a disaggregated architecture, which may be configured to utilize a protocol stack physically or logically distributed among two or more network entities 102, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 102 may include one or more of a central unit (CU), a distributed unit (DU), a radio unit (RU), a RAN Intelligent Controller (RIC) (e.g., a Near-Real Time RIC (Near-RT RIC), a Non-Real Time RIC (Non-RT RIC)), a Service Management and Orchestration (SMO) system, or any combination thereof.

An RU may also be referred to as a radio head, a smart radio head, a remote radio head (RRH), a remote radio unit (RRU), or a transmission reception point (TRP). One or more components of the network entities 102 in a disaggregated RAN architecture may be co-located, or one or more components of the network entities 102 may be located in distributed locations (e.g., separate physical locations). In some implementations, one or more network entities 102 of a disaggregated RAN architecture may be implemented as virtual units (e.g., a virtual CU (VCU), a virtual DU (VDU), a virtual RU (VRU)).

Split of functionality between a CU, a DU, and an RU may be flexible and may support different functionalities depending upon which functions (e.g., network layer functions, protocol layer functions, baseband functions, radio frequency functions, and any combinations thereof) are performed at a CU, a DU, or an RU. For example, a functional split of a protocol stack may be employed between a CU and a DU such that the CU may support one or more layers of the protocol stack and the DU may support one or more different layers of the protocol stack. In some implementations, the CU may host upper protocol layer (e.g., a layer 3 (L3), a layer 2 (L2)) functionality and signaling (e.g., Radio Resource Control (RRC), service data adaption protocol (SDAP), Packet Data Convergence Protocol (PDCP)). The CU may be connected to one or more DUs or RUs, and the one or more DUs or RUs may host lower protocol layers, such as a layer 1 (L1) (e.g., physical (PHY) layer) or an L2 (e.g., radio link control (RLC) layer, medium access control (MAC) layer) functionality and signaling, and may each be at least partially controlled by the CU.

Additionally, or alternatively, a functional split of the protocol stack may be employed between a DU and an RU such that the DU may support one or more layers of the protocol stack and the RU may support one or more different layers of the protocol stack. The DU may support one or multiple different cells (e.g., via one or more RUs). In some implementations, a functional split between a CU and a DU, or between a DU and an RU may be within a protocol layer (e.g., some functions for a protocol layer may be performed by one of a CU, a DU, or an RU, while other functions of the protocol layer are performed by a different one of the CU, the DU, or the RU).

A CU may be functionally split further into CU control plane (CU-CP) and CU user plane (CU-UP) functions. A CU may be connected to one or more DUs via a midhaul communication link (e.g., F1, F1-c, F1-u), and a DU may be connected to one or more RUs via a fronthaul communication link (e.g., open fronthaul (FH) interface). In some implementations, a midhaul communication link or a fronthaul communication link may be implemented in accordance with an interface (e.g., a channel) between layers of a protocol stack supported by respective network entities 102 that are in communication via such communication links.

The core network 106 may support user authentication, access authorization, tracking, connectivity, and other access, routing, or mobility functions. The core network 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a Packet Data Network (PDN) gateway (P-GW), a user plane function (UPF)), or a location management function (LMF), which is a control plane entity that manages location services. In some implementations, the control plane entity may manage non-access stratum (NAS) functions, such as mobility, authentication, and bearer management (e.g., data bearers, signal bearers, etc.) for the one or more UEs 104 served by the one or more network entities 102 associated with the core network 106.

The core network 106 may communicate with the packet data network 108 over one or more backhaul links 116 (e.g., via an S1, N2, N6, or another network interface). The packet data network 108 may include an application server 118. In some implementations, one or more UEs 104 may communicate with the application server 118. A UE 104 may establish a session (e.g., a protocol data unit (PDU) session, or the like) with the core network 106 via a network entity 102. The core network 106 may route traffic (e.g., control information, data, and the like) between the UE 104 and the application server 118 using the established session (e.g., the established PDU session). The PDU session may be an example of a logical connection between the UE 104 and the core network 106 (e.g., one or more network functions of the core network 106).

In the wireless communications system 100, the network entities 102 and the UEs 104 may use resources of the wireless communication system 100 (e.g., time resources (e.g., symbols, slots, subframes, frames, or the like) or frequency resources (e.g., subcarriers, carriers) to perform various operations (e.g., wireless communications). In some implementations, the network entities 102 and the UEs 104 may support different resource structures. For example, the network entities 102 and the UEs 104 may support different frame structures. In some implementations, such as in 4G, the network entities 102 and the UEs 104 may support a single frame structure. In some other implementations, such as in 5G and among other suitable radio access technologies, the network entities 102 and the UEs 104 may support various frame structures (i.e., multiple frame structures). The network entities 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. The first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally or alternatively, a time interval of a resource (e.g., a communication resource) may be organized according to slots. For example, a subframe may include a number (e.g., quantity) of slots. Each slot may include a number (e.g., quantity) of symbols (e.g., orthogonal frequency division multiplexing (OFDM) symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHZ), FR2 (24.25 GHz-52.6 GHz), FR3 (7.125 GHz-24.25 GHz), FR4 (52.6 GHZ-114.25 GHZ), FR4a or FR4-1 (52.6 GHz-71 GHz), and FR5 (114.25 GHz-300 GHz). In some implementations, the network entities 102 and the UEs 104 may perform wireless communications over one or more of the operating frequency bands. In some implementations, FR1 may be used by the network entities 102 and the UEs 104, among other equipment or devices for cellular communications traffic (e.g., control information, data). In some implementations, FR2 may be used by the network entities 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

A UE 104 includes a factor generation system 120. The factor vector generation system 120 generates, receives, or otherwise obtains a vector (also referred to as an original vector) having unit Euclidean length. The factor vector generation system 120 factorizes the vector using KRF or column-wise KPD to generate at least two factor vectors and such that a metric (e.g., cosine similarity or cosine distance) is satisfied. Each of the factor vectors has fewer elements than the original vector. The UE 104 transmits the factor vectors 122 to the network entity 102 that includes a vector reconstruction system 124 that reconstructs the original vector from the factor vectors, such as by generating a Khatri-Rao product of the factor vectors.

Communication between devices discussed herein, such as between UEs 104 and network entities 102, is performed using any of a variety of different signaling. For example, such signaling can be any of various messages, requests, or responses, such as triggering messages, configuration messages, and so forth. By way of another example, such signaling can be any of various signaling mediums or protocols over which messages are conveyed, such as any combination of radio resource control (RRC), downlink control information (DCI), uplink control information (UCI), sidelink control information (SCI), medium access control element (MAC-CE), sidelink positioning protocol (SLPP), PC5 radio resource control (PC5-RRC) and so forth.

Techniques for encoding, compressing, or approximating a data vector having unit Euclidean length (also referred to as unit norm) with cosine similarity or, equivalently, cosine distance as the metric for measuring how close the decoded, decompressed, or approximated version of the vector is compared to the original vector. Cosine similarity or cosine distance is a useful metric for comparing two vectors in various different contexts. One such context is wireless networks, where vectors are used for beamforming or precoding over MIMO wireless channels. Another such context is AI/ML, where the vectors include distinct attributes (of, for example, a document or an image) and are used as inputs to an AI/ML model for inference (e.g., prediction or classification).

A wireless network operating over a wireless MIMO channel will have multiple antennas at the transmitting node and multiple antennas at the receiving node. For example, consider a UE having r antennas and a network entity (e.g., a base station), equipped with t antennas. Such a wireless channel between the network entity and the UE has a total of rt number of paths. In the downlink communication, where the network entity sends information to the UE, the discrete-time channel can be represented as a r×t dimensional complex-valued matrix H, with element hᵢⱼ of H denoting the complex-valued channel gain between i^{th} receive antenna and j^{th} transmit antenna, 1≤i≤r, 1≤j≤t.

As can be understood, the wireless channel gains, or the channel matrix H depends on the physical propagation medium and due to the dynamic nature of the physical propagation medium, the wireless channel is a time-varying channel. Further, the channel gains depend on the frequency of operation—with a multicarrier waveform, such as orthogonal frequency division multiplexing (OFDM), the channel matrix can assume different values at different sub-carriers (e.g., frequencies) at the same instant of time. In other words, the wireless channel matrix H is stochastic in nature, varying across time, frequency, and spatial dimensions. By adapting the transmission method as per the channel realization (channel realization implies a particular instantiation of the stochastic channel matrix H) and/or pre-processing the information signal to be transmitted according to the current channel realization, better throughput over the communication link ca be achieved while making the link more reliable.

To achieve such an adaptive transmission or to implement pre-processing at the transmitter, the CSI is used at the transmitter. This amounts to the transmitter knowing the channel matrix H over the entire frequency range of operation (e.g., at every sub-carrier in the case of OFDM/multi-carrier waveforms) every time the channel changes.

The receiver can estimate the channel through reference or pilot signals sent by the transmitter. One method for the transmitter to acquire the channel knowledge is through the receiver sending back or feeding back the CSI it acquired. Thus, in a downlink communication (e.g., from a network entity to a UE), the UE estimates the downlink CSI (typically, the channel matrix, or the channel covariance matrix) with the help of pilot or reference signals sent by the network entity and the UE sends back the estimated CSI to the network entity. Similarly, in the uplink communication (e.g., from a UE to the network entity), the network entity estimates the CSI based on uplink reference or pilot signals from the UE and feeds back the CSI to the UE.

CSI can include one or more characteristics of the channel realization, such as the rank of the channel matrix (e.g., rank indicator (RI)), a measure of the quality of the channel realization (e.g., channel quality indication (CQI)), channel covariance, eigen vectors of the channel matrix, singular vectors of the channel matrix, and so forth. It is more practical to feed back one or more of the right singular vectors of the channel matrix, along with an indication of the corresponding singular values (which serves as a CQI of the spatial channels corresponding to the singular vectors). The importance of right singular vectors of the channel matrix stems from the fact that they can be used as precoding vectors at the transmitter to beamform the information towards the receiver and such a beamforming would result in improved utilization of the MIMO channel. Similarly, the eigen vectors of the channel matrix also determine the optimal spatial directions for beamforming the information towards the receiver from the transmitter. Thus, feedback of CSI, where the CSI includes of the right singular vectors of the channel or the eigen vectors of the channel is an important case to be considered.

However, CSI feedback information is an overhead for the wireless network as it does not include user data. The challenge is to reduce the CSI overhead sent in the form of feedback from the UE while allowing the base station to acquire CSI of sufficient quality to enable it to improve the communication over the link. The quality of CSI, especially when the CSI includes the right singular vectors or eigen vectors of the channel that will be used for beamforming at the transmitter, can be measured in terms of cosine similarity or cosine distance between the actual singular or eigen vectors and the vectors made available at the transmitter node through CSI feedback. The cosine similarity between the actual singular or eigen vectors of the channel and the vectors in the feedback to and made available at the transmitter (e.g., network entity in downlink) should be as high as possible. Equivalently, the cosine distance between the actual singular or eigen vectors of the channel and the vectors in the feedback to and made available at the transmitter (e.g., network entity in downlink) should be as small as possible.

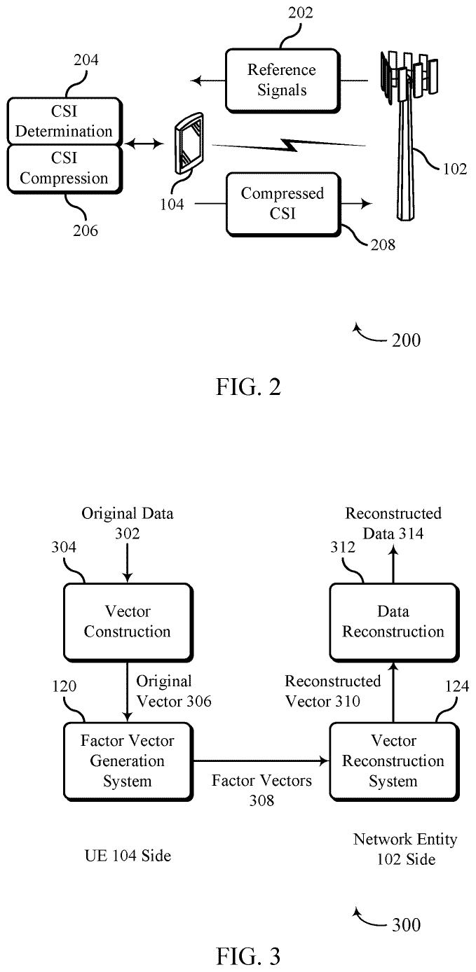

FIG. 2 illustrates an example 200 of providing CSI feedback using vector compression based on satisfying a metric in accordance with aspects of the present disclosure. In a downlink communication (from a network entity 102 to a UE 104), the network entity 102 transmits reference signals 202 that the UE 104 receives. The UE 104 performs CSI determination 204 to estimate the downlink CSI (e.g., generates a channel matrix H or channel covariance matrix) and CSI compression 206 to compress the CSI. The CSI includes the right singular vectors or eigen vectors of a channel that will be used for beamforming at the network entity 102 and the CSI compression 206 generates the compressed CSI 208 by factorizing each vector using KRF or column-wise KPD to generate at least two factor vectors and such that a metric (e.g., cosine similarity or cosine distance) is satisfied. The UE 104 then transmits the compressed CSI 208 to the network entity 102. Similarly, in the uplink communication from the UE 104 to the network entity 102, the network entity 102 estimates the CSI based on uplink reference or pilot signals from the UE 104 and feeds back the compressed CSI to the UE 104.

In AI/ML models used to make inferences in many domains, such as in natural language processing and computer vision, cosine similarity or cosine distance can play a key role. For example, to find the similarity between two documents or to distinguish between two documents, a vector is constructed for each document. The length of such a vector, for each document, is equal to the number of unique words in the document and the value of each element in the vector is equal to the number of times a particular word appears in the document. Similarity between the two documents is determined based on the cosine similarity between the two vectors (or a normalized or scaled version of the two vectors corresponding to the two documents. In computer vision, in a similar manner, the AI/ML models use cosine similarity between the vectors constructed from different images to infer similarity or separation between the images. On some occasions, it such vectors (e.g., the vectors constructed based on documents or images) are transmitted or sent from one device to another device. For example, a UE may want to determine similarity or inference between two images and the AI/ML model that can make the inference might be located at network entity, such as a gNB. Then, the UE will construct the vectors and transmit them to the network entity. To conserve the communication resources used for transmitting the vectors, the vectors are compressed before transmission. At the same time, as cosine similarity between the two vectors can be a key determining factor to make the inference, the two vectors received at the network entity should be similar to the vectors computed by the UE in terms of cosine similarity. In another example, an AI/ML model such as a hyper-spherical prototypical network performs classification and regression with cosine distance as the distance measure between different feature vectors. When transmitting feature vectors computed at a user node to such an AI/ML model located at a distant network entity, communication resources are saved by compressing the vectors while preserving or maintaining the cosine similarity. In other words, the vectors are compressed before transmitting them and at the same time, in order to not compromise on the accuracy, it is desirable to have the vectors received at the input of the AI/ML model to have a zero or small cosine distance with the vectors computed at the user node.

Thus, cosine similarity, and equivalently cosine distance, between two vectors plays a key role in some of the domains (e.g., at least in wireless networks and AI/ML models). Encoding a vector into a few parameters, or compressing a vector or approximating a given vector with a few parameters, to save the amount of communication resources while ensuring a zero or small loss in cosine similarity (or, equivalently, a zero or small Cosine distance) is desirable.

FIG. 3 illustrates an example of providing data using vector compression based on satisfying a metric in accordance with aspects of the present disclosure. The UE 104 obtains or generates original data 302, such as two documents or two images, and desires to transmit the original data 302 to the network entity 102 to have an AI/ML model at the network entity 102 (or accessible to the network entity 102) determine the similarity of the two documents or two images. For each document or image, vector construction 304 is performed to convert the document or image into an original vector 306. The factor vector generation system 120 factorizes the original vector 306 using KRF or column-wise KPD to generate at least two factor vectors 308 and such that a metric (e.g., cosine similarity or cosine distance) is satisfied. Each of the factor vectors 308 has fewer elements than the original vector. The UE 104 transmits the factor vectors 308 to the network entity 102 that includes the vector reconstruction system 124 that reconstructs the original vector from the factor vectors, such as by generating a Khatri-Rao product of the factor vectors, to generate a reconstructed vector 310. Data reconstruction 312 is performed to convert the reconstructed vector 310 into reconstructed data 314 (e.g., documents or images).

Returning to FIG. 1, the techniques discussed herein describe a lossy compression method for compressing a vector having unit Euclidean length (also referred to as unit norm). A given unit norm vector is factorized into a product of two or more factor vectors having smaller dimensions than the original vector using KRF or, equivalently, column-wise KPD. The vector reconstructed from its factor vectors will have a higher cosine similarity, or equivalently, smaller cosine distance, from the original vector. Reference is made herein to using the techniques for singular vectors or eigen vectors of a wireless channel matrix, the techniques discussed herein are equally applicable to any vector having unit norm.

Consider wireless communication between a UE, equipped with r antennas and a network entity, equipped with t antennas. For the purpose of illustration, downlink communication where the network entity sends information to the UE over the wireless channel from network entity to UE is discussed, characterized by the matrix H∈ [symbol] ^{r×t}. Channel state information is made available at the network entity, through feedback from the UE. The UE determines the channel matrix H, based on pilot or reference signals transmitted by the network entity, and then the UE may either choose to compress and send the channel matrix H to the network entity or one of the following information may be derived from the channel matrix.

The following notation is used while describing the technical details in the following. For a length-t column vector a∈ [symbol] ^{1×t}, or a row vector a∈ [symbol] ^{r×1}, aᵢ denotes the i^{th} element of the vector. For a matrix A∈ [symbol] ^{r×t}, aᵢⱼ, A_{i,1:t}, A_{1:r,j} denotes (i, j)^{th} element, i^{th} row, j^{th} column of matrix A, respectively. A block of matrix A consisting of elements in row i to i′ and column j to j′ is denoted by A_{i:i′,j:j′}. Superscript T and superscript * denotes conjugate transpose (also known as Hermitian transpose) of a vector or a matrix. Thus, for a vector a, a^{T} denotes transpose of a, and a* denotes conjugate transpose (or Hermitian) of a and the same holds true for a matrix A. Note that, for a real-valued vector a, conjugate transpose is equivalent to transpose, i.e., a*=a^{T} and similarly, for a real-valued matrix A, A*=A^{T} Further, ∥a∥ denotes Euclidean length or equivalently Euclidean norm of vector a and ∥a∥_{F} denotes Frobenius norm of vector a.

Channel eigen vectors (eigen vectors of the channel matrix) can be obtained using eigen decomposition (ED) of H when r=t. Assuming r=t, Eigen vectors of H can be determined from the ED of matrix H:

$$E D ( H ) = W D {W}^{*}$$

where W∈ [symbol] ^{r×r} is an r×r matrix including orthonormal column vectors, which are the eigen vectors of H, and D is a diagonal matrix of size r×r where dᵢᵢ, 1≤i≤r, are the eigen values of H, where d₁₁≥d₂₂≥ . . . ≥dᵣᵣ. For convenience, the second subscript from dᵢᵢ is skipped and dᵢᵢ is written as dᵢ.

When r<t, eigen vectors of HH* can be determined from the ED of matrix HH* and when r>t, eigen vectors are determined through eigen decomposition of matrix HH*.

Singular vectors of H can be computed through singular value decomposition (SVD):

$$SVD ( H ) = {USV}^{*}$$

where U∈ [symbol] ^{r×r} is a size r×r unitary matrix and V∈ [symbol] ^{t×t} is a size t×t unitary matrix including left and right singular vectors, respectively, of H. S is a diagonal matrix of size r×t where sᵢᵢ, 1≤i≤R, are the singular values of H, where s₁₁>s₂₂≥ . . . ≥s_{RR} and R=min(r, t). For convenience, the second subscript from sᵢᵢ is skipped and sᵢᵢ is written as sᵢ.

Note that the U and V are unitary matrices, or, equivalently, orthonormal matrices. Column vectors of U are denoted by u₁, . . . , uᵣ, where uᵢ∈ [symbol] ^{r×1}, i=1, . . . , r, and column vectors of V* are denoted by

$${v}_{1}^{*} , … , {v}_{t}^{*}$$

where v*ᵢ∈ [symbol] ^{1×t}, i=1, . . . , t.

The unitary (or, equivalently, the orthonormality) property of matrices U and V implies that the Euclidean length, or, equivalently, the L2 norm, or [symbol] 2-norm, or square norm, or 2-norm, or, simply the “norm” of every column vector of U and V is equal to one, i.e., ∥v*ᵢ∥=1, i=1, . . . , t and ∥uᵢ∥=1, i=1, . . . , r.

To beamform the information signal towards the receiver (e.g., the UE) in an advantageous manner, it would be sufficient for the transmitter (e.g., the network entity in this case) to know the right-singular vectors of the channel towards the UE along with the corresponding singular values that represent the quality of each of the virtual spatial channel or beam helping the transmitter to determine the data rate and transmit power to configure for each virtual spatial channel or beam.

In some situations, depending on the relative strengths of the singular values, the UE may decide to send only a few of the right-singular vectors but not all of them. In such a case, the UE inputs a set of orthonormal vectors (e.g., the selected few right-singular vectors) to the encoder neural network (NN). The decoder NN at the network entity reconstructs or reproduces these set of orthonormal vectors.

Note that, the right singular vectors, used by the transmitter to beamform information towards the UE, are also called “precoding” vectors. As a simple example, consider r=2, t=8, resulting in H∈ [symbol] ^{2×8} and only the first two right singular vectors corresponding to the highest two singular values are sent back to the transmitter (e.g., the network entity) by the receiver (e.g., the UE) and the transmitter carries on rank-2 transmission, e.g., it transmits two symbols, x₁ and x₂, per one channel use over the MIMO channel H. The transmitter precodes symbol x₁ with the first right singular vector v₁, precodes symbol x₂ with the second right singular vector v₂ and transmits v₁x₁+v₂x₂ over the channel. The precoded transmitted information symbols go through the 2×8 matrix channel H. The receiver uses the first two left singular vectors to receive r number of received symbols, removing the interference from the other spatial channels, and subsequently estimating the transmitted symbols x₁ and x₂.

Such a beamforming or precoding procedure ensures that the symbol x₁ is transmitted along the direction of the first right singular vector and, as each singular vector of H is orthogonal to all the other right singular vectors, the symbol x₁ would not suffer from any interference from the symbols transmitted along the directions of other right singular vectors (e.g., in the example being considered here, symbol x₂ would not cause any interference to symbol x₁). Similarly, by precoding symbol x₂ with the second right singular vector v₂, symbol x₂ is transmitted along the direction of the second right singular vector and, as each singular vector is orthogonal to all the remaining right singular vectors, the symbol x₂ would not suffer from any interference from the symbols transmitted along the directions of other right singular vectors (e.g., in the example being considered here, symbol x₁ would not cause any interference to symbol x₂ and vice-versa).

Consider a practical scenario where the CSI feedback from the receiver (e.g., UE) includes one or more right singular vectors of the channel. Each singular vector consists of floating-point complex-valued elements, and it uses an infeasibly large amount of communication resources to feedback the singular vectors with full-precision. As CSI feedback is an overhead to the wireless network, it is desirable to reduce the CSI feedback. Hence, the singular vectors may be fed back by employing suitable compression and/or quantization techniques. In some CSI feedback techniques, compression is achieved by quantizing the singular vectors using a pre-defined codebook or vector quantization schemes. In some other CSI feedback techniques, first the vectors are compressed based on a compression scheme and the compressed information is further quantized before transmission.

Due to compression and/or quantization of the information (e.g., the singular vectors in this case) transmitted over the wireless channel and due to possible channel distortions including the degrading effects of additive noise, there would be a non-zero probability of error in the received information (e.g., the right singular vectors) at the other node, e.g., the network entity in our example. Using the illustrative example discussed above, consider that the CSI feedback includes right singular vector v₁ and v₂ and the network entity receives the vectors \hat{v}₁ and \hat{v}₂, where \hat{v}ᵢ may or may not be equal to vᵢ for i=1, 2, due to quantization at the transmitting device and possible channel distortions and noise, as discussed above. Even if one of the vectors, either \hat{v}₁ or \hat{v}₂ are in error, it is highly likely that they would no longer be mutually orthogonal. Further, a right singular vector received in error would not be orthogonal to other right singular vectors. As the network entity precodes its transmit symbols with the vectors it receives through CSI feedback, the precoded vectors would be \hat{v}₁ and \hat{v}₂ for symbols x₁ and x₂, respectively. Assume that only \hat{v}₁ is in error, e.g., \hat{v}₁≠v₁ and \hat{v}₂=v₂. When the direction of \hat{v}₁ deviates or is different from the direction of v₁, and when the information symbol x₁ is precoded with \hat{v}₁, then:
symbol x₁ suffers interference from the symbols transmitted along the directions of other right singular vectors, i.e., from the symbol x₂ precoded with \hat{v}₂=v₂;
the channel gain experienced by symbol x₁ is no longer equal to s₁, the first singular value of the channel—this would further result in appropriate usage of the available channel and degradation in the reliability of the received information at the UE.

As can be readily understood, the situation or degrading effects would be the same if \hat{v}₁=v₁ and \hat{v}₂≠v₂ and it would result in further degradation of the communication link when \hat{v}₁≠v₁ and \hat{v}₂≠v₂.

In such a beamforming or precoding procedure, it is important that the direction of precoding vectors align more accurately with the directions of the right singular vectors of the channel. Hence, when CSI feedback includes channel singular vectors or the eigen vectors, it is important that the singular or eigen vectors made available at the transmitter (e.g., the network entity) have their spatial directions the same or close to that of the original singular or eigen vectors.

Thus, a useful criterion for a CSI compression or quantization method is to reduce (e.g., minimize) the directional or angular distance or increase (e.g., maximize) the directional or angular similarity between the singular or eigen vectors made available at the transmitter and the original singular or eigen vectors of the channel. The angular similarity between two-dimensional vectors can be measured using the concept of cosine similarity, discussed below.

Cosine similarity is a measure of similarity between two non-zero multi-dimensional vectors, especially when the two vectors are compared with respect to the directions in which they are pointing. Cosine similarity (CS) between two non-zero real-valued vectors, a∈ [symbol] ^{n×1} and b∈ [symbol] ^{n×1}, is given by the dot product of a and b divided by the product of length of a and length of b and can be expressed as

$$C S ( a , b ) = \frac{a \cdot b}{‖ a ‖ ‖ b ‖} = \frac{{\sum }_{i = 1}^{n} {a}_{i} {b}_{i}}{\sqrt{{\sum }_{i = 1}^{n} {a}_{i}^{2}} \sqrt{{\sum }_{i = 1}^{n} {b}_{i}^{2}}}$$

where a·b denotes the dot product of vectors a and b, and ∥a∥, ∥b∥ denote the Euclidean length of vector a and b, respectively. Note that Euclidean length of a vector is also called Euclidean norm, or simply “norm”, L² norm, [symbol] ²-norm, square norm or, 2-norm and is given by the square root of the sum of the squares of its elements, e.g., for a vector a, the Euclidean length is given by

$$‖ a ‖ = \sqrt{{\sum }_{i = 1}^{n} {a}_{i}^{2}} .$$

Further, it should be noted that Euclidean length of a vector is also equal to the Frobenius norm of a vector, e.g., ∥a∥=∥a∥_{F}. When a and b are column vectors,

$$a \cdot b = {a}^{T} b = {b}^{T} a = {\sum }_{i = 1}^{n} {a}_{i} {b}_{i}$$

and when a and b are row vectors,

$$a \cdot b = {ab}^{T} = b {a}^{T} = {\sum }_{i = 1}^{n} {a}_{i} {b}_{i} .$$

As can be seen from the above formula, cosine similarity between two non-zero real-valued vectors is the cosine of the angle between the vectors. CS(a, b), the value of cosine similarity between two arbitrary non-zero real-valued vectors can take any value between −1 to +1, e.g., CS(a, b)∈[−1, +1]. CS(a, b)=−1 implies that the two vectors a and b point towards exactly opposite directions, CS(a, b)=0 implies that the two vectors are orthogonal to each other (or, the two vectors are not at all correlated) and CS(a, b)=1 implies that the two vectors point towards exactly the same direction (or the two vectors are completely similar to each other with respect to their pointing directions).

Cosine distance (CD) is an equivalent metric to the cosine similarity metric and is defined as

$$CD ( a , b ) = 1 - ( a , b )$$

Cosine distance between two non-zero real-valued vectors a and b is an equivalent metric to that of cosine similarity. However, it should be noted that CD is a not a true distance metric as it does not satisfy the triangle inequality.

When ∥a∥²=1 and ∥b∥²=1, e.g., when vectors a and b have unit Euclidean length or unit Euclidean distance, or equivalently, when the norm, or L²-norm, or the 2-norm or the square-norm of the vectors a and b is equal to one, then the cosine distance between them is given by

$$CD ( a , b ) = \frac{{‖ a - b ‖}^{2}}{2}$$

where ∥a−b∥² is the square of the Euclidean distance between the vectors a and b. The above relation between the cosine distance and the Euclidean distance between two vectors when the vectors have their norm, or Euclidean length equal to one is useful in the context of the techniques discussed herein. This indicates that, when the vectors are of unit norm or of unit Euclidean length, the cosine distance between them can be reduced (e.g., minimized) by reducing (e.g., minimizing) the Euclidean distance between them. As a consequence, we can increase the cosine similarity between two vectors by reducing (e.g., minimizing) the Euclidean distance between the vectors, or equivalently, the mean square error between the two vectors, when the vectors have unit Euclidean length or unit length. This is also equivalent to stating that when the two vectors are closer in least square sense, they would be closer in mean square sense and in Euclidean distance, thereby will have a higher Cosine similarity.

Feedback of channel singular vectors or channel eigen vectors or precoding vectors is an overhead that is to be kept low. Note that, as the singular or eigen vectors are used at the transmitter (e.g., the network entity in a downlink communications) for precoding the information symbol(s), the singular or eigen vectors that are feedback are also referred to as precoding vectors. Some techniques to reduce (e.g., minimize) this signaling overhead include quantization and AI/ML model based CSI compression.

With quantization, the singular, eigen, or precoding vectors are quantized such that the number of bits required to transmit the information vector is reduced (e.g., minimized). Quantization could be a simple scalar quantization or a more complex, but effective, vector quantization, or it could be a combination of both. One approach is codebook quantization, where the vectors are quantized with respect to some predefined codebooks. Quantization can be considered as a form of lossy compression where the loss in information increases with the amount of compression.

With resect to AI/ML model, especially the paradigm of deep learning (DL), the power of deep neural networks (DNN) can be used for finding more efficient solutions for the problems that arise in transmission and reception of information over wireless channels. One such use is making CSI available at the transmitter.

Autoencoders may be used for CSI compression. An autoencoder is a deep neural network that can be used for dimensionality reduction. An autoencoder includes two parts, an encoder E_{ω}, which is a DNN with learnable or trainable parameters denoted by ω, and a decoder D_{ψ}, which is another DNN with ψ as its set of trainable or learnable parameters. The encoder learns a representation of the input signal or data (in other words, encodes the input signal/data) such that the key attributes of the input signal or data are captured as low-dimensional feature vector(s). The decoder validates the encoding and helps the encoder to refine its encoding by trying to regenerate the input signal or data from the feature vectors generated by the encoder. Thus, the encoder and the decoder are trained and developed together such that the signal or data at the input to the encoder is reconstructed, as faithfully as possible, at the output of the decoder. Thus, the two neural networks, or the two models E_{ω} and D_{ψ} together constitutes an autoencoder.

An autoencoder based method for CSI compression for a wireless network can be explained as follows. For illustrative purposes, consider downlink communication, from the network entity to the UE. An autoencoder is trained to efficiently encode and decode the channel matrices; e.g., the training data set includes a large number of wireless channel matrices (e.g., collected from the field or generated through simulations) and the autoencoder is trained such that the encoder generates a lower-dimensional latent representation of the input channel matrix and the decoder reconstructs the channel matrix from the latent representation generated by the encoder. After training, the encoder part of the autoencoder, E_{ω}, is deployed at the UE and the decoder part of the autoencoder, D_{ψ}, is deployed at the network entity. The UE estimates the channel matrix using the reference or pilot signals received from the network entity, encodes the channel matrix using the encoder E_{ω}, and transmits the encoded output (feature vectors or latent representation of channel matrix) computed by the encoder over the wireless channel towards the network entity. The network entity, using the decoder D_{ψ}, decodes or reconstructs the channel matrix from the feature vectors received from the UE. As the autoencoder achieves a high amount of dimensionality reduction, a good amount of compression of CSI information transmitted over the channel may be achieved using this method. Note that the compressed CSI data at the output of the encoder is nothing but “features or feature vectors” computed by the encoder.

As discussed above, often it would be enough for the transmitter to know the right-singular vectors or the eigenvectors of the channel matrix in place of channel matrix itself. The autoencoder based CSI compression method, discussed above, can also be used for sending the singular vectors or eigenvectors of the channel matrix. In such a case, the autoencoder would be trained to efficiently represent or compress a matrix including the singular vectors or eigenvectors.

The techniques discussed herein reduce the amount of signaling overhead used to convey the channel singular or eigen vectors, or precoding vectors, by compressing the singular, eigen, or precoding vectors by a vector into at least two factor vectors each having a smaller length than the original vector through KRF, as discussed in more detail below. The technique can be summarized as follows. A singular, eigen, or precoding vector is factorized into two or more lower dimensional vectors, referred to Khatri-Rao (KR) factor vectors, using KRF. The smaller length KR factor vectors are fed back from a receiver node (e.g., the UE in case of downlink) to a transmitter node (e.g., the network entity in case of downlink). At the decoder input, the full-length singular, eigen, or precoding vector is reconstructed by generating a KR product of the KR factor vectors.

The techniques discussed herein can be considered as a compression in the numerical domain. In one or more implementations, the techniques discussed herein can complement other methods or techniques. Accordingly, the techniques discussed herein can bring additional compression when used jointly with other methods, such as quantization or an AI/ML model discussed above.

For example, the techniques discussed herein can be used along with methods for quantization of the singular, eigen, or precoding vectors as follows. Instead of quantizing the full-length singular, eigen, or precoding vector, first the full-length singular, eigen, or precoding vector is factorized into two (or more) shorter length vectors and those two (or more) short vectors are quantized following the methods of quantization discussed above.

By way of another example, the techniques discussed herein can be used jointly with AI/ML based CSI compression. After factorizing a singular, eigen, or precoding vector into two (or more) lower length factor vectors, the AI/ML model can be used to further compress the lower length factor vectors. This way, the AI/ML model need not work on compressing singular, eigen, or precoding vectors having a large length, but instead the AI/ML model can work on factor vectors having a much smaller length. This can result in AI/ML models of lower dimensionality and lower complexity and the resulting compression of the overhead can also be higher than what would be achieved when using only the AI/ML models without factorizing the vectors.

The techniques discussed herein are based on KRF or, equivalently, Khatri-Rao product Approximation (KRPA) of vectors. The techniques discussed herein are described considering real-valued vectors, e.g., the KRF/KRPA methods are described in the following for factorizing real-valued vectors. However, in general, singular vectors, or eigen vectors of a wireless channel are complex-valued vectors, elements have a real part and an imaginary part. As the equivalence between the cosine distance and the Euclidean distance (note that mean square error is directly proportional to the Euclidean distance) discussed above holds true for real valued vectors, the techniques discussed herein are described for real-valued vectors by converting each complex-valued vector into a corresponding real-valued vector through a one-to-one mapping.

While mapping a given complex-valued singular, eigen, or precoding vector into a real-valued vector, the mapping is a one-to-one mapping so that the complex-valued vector can be uniquely recovered from its real-valued version. Further, this mapping is known at both the transmitting node and receiving node (e.g., at the UE and network entity). One such mapping that may be used in compressing channel singular or eigen vectors, or precoding vectors, is as follows: let v∈ [symbol] ^{n×1} be the given complex-valued singular/eigen/precoding vector. It can be converted into a size 2n×1 real-valued vector by concatenating the imaginary values of the vector below the real values of the vector:

Construct v_{Re}∈ [symbol] ^{2nx1}, where,

$${v}_{R e} = [ \begin{matrix}Real ( v ) \\ Imag ( v )\end{matrix} ]$$

It should be noted that the KRF or KRPA techniques discussed herein work for complex-valued vectors and the KRF techniques factorize a given complex-valued vector into two factor vectors, each one of which is a shorter length complex-valued vector. However, when the full-length vector is reconstructed from the KR product of the two factor vectors, the resultant reconstructed vector need not be close in cosine similarity or cosine distance to the original full-length vector. When working with real valued vectors, by first converting a complex-valued vector into a real valued vector and then performing the KRF, the reconstructed vector from factor vectors through KR product will be close to the original full-length vector in the cosine similarity or cosine distance.

It should be noted that conversion to real-valued vectors, as discussed above, need not be performed when the vector that is to be compressed is a real-valued vector. For example, the vectors in the domain of AI/ML are typically real-valued and there is no need to convert them again into real-valued vectors.

The following notation is used herein. For a length-t column vector a∈ [symbol] ^{1×t}, or a row vector a∈ [symbol] ^{r×1}, aᵢ denotes the i^{th} element of the vector. For a matrix Z∈ [symbol] ^{r×t}, zᵢⱼ, Z_{i,1:t}, Z_{1:r,j} denote (i, j)^{th} element, i^{th} row, j^{th} column of matrix Z, respectively. A block of matrix Z consisting of elements in row i to i′ and column j to j′ and is denoted by Z_{i:i′,j:j′}. Superscript T and superscript * denotes conjugate transpose (also known as Hermitian transpose) of a vector or a matrix. Thus, for a vector a, a^{T} denotes transpose of a, and a* denotes conjugate transpose (or, Hermitian) of a and the same holds true for a matrix A. Note that, for a real-valued vector a, conjugate transpose is equivalent to transpose, i.e., a*=a^{T} and similarly, for a real-valued matrix A, A*=A^{T}. Finally, ∥a∥_{F} denotes Frobenius norm of vector a.

Consider vectors a and b having real-valued elements with dimensions n₁×1 and n₂×1, respectively, which implies that a∈ [symbol] ⁿ^{₁}^{×1}, b∈ [symbol] ⁿ^{₂}^{×1} in formal mathematical notation. The column-wise KR product, also referred to as the column-wise Kronecker product or column-wise matrix direct product, of a and b, denoted by a⋄b, is defined as

$$c = a ◇ b = {[ {a}_{1} {b}^{T} {a}_{2} {b}^{T} … {a}_{{n}_{1}} {b}^{T} ]}^{T} ∈ {ℝ}^{{n}_{1} {n}_{2} \times 1} \qquad ( 1 )$$

The column-wise KR product indicates that, through column-wise KR product, two smaller-length vectors construct a larger length vector. In equation (1), the vectors a and b are referred to as the KR factor vectors (or, simply, factors), of vector c.

The KRF finds (smaller length) KR factor vectors for a given (larger length) vector. In the following, the KRF (also referred to as KR approximation) of a given vector is discussed.

With respect to single-term KRF, consider a vector c∈ [symbol] ^{n×1} where n=n₁×n₂. The single-term KRF determines the vectors a∈ [symbol] ⁿ^{₁}^{×1}, b∈ [symbol] ⁿ^{₂}^{×1} such that a⋄b is a close approximation of c in the least-squares sense. Equivalently, a⋄b is a close approximation of c with Euclidean distance as the metric that quantifies the closeness of the approximation.

As the vector c is being approximated with a single KR product term (including vectors a and b), the approximation is referred to as single-term KRF to distinguish it from other cases, discussed in more detail below, where the KR product involves multiple terms, with each term involving two smaller-length vectors.

Furthermore, it should be noted that expressing a vector as a KR product of two vectors may also be referred to KRPA, as the KR product of the KR factor vectors a and b may not exactly be the same as original vector c.

When vectors a and b are found, vector c can be reconstructed (possibly, with a tolerable difference between the reconstructed vector and the original vector) through column-wise KR product of a and b. Thus, when elements of c are to be communicated or transmitted over a communication channel, only elements of a and b can be communicated. Accordingly, only n₁+n₂ elements or real-numbers can be transmitted to represent n₁n₂ elements or real-numbers, where n=n₁n₂. This results in considerable savings in the communication resources and the amount of overhead. This is also the case when elements of c are stored in memory-instead of storing the elements of c, the elements of a and b can be stored. It should be noted that the word “term” is used synonymously with the word “component” in herein.

A procedure or algorithm for single-term least squares KRF or single-term KRPA is as follows. In the following, vec refers to a vectorization operator that converts any given matrix into a vector by stacking its columns. For a r×t dimensional matrix Z,

$$v e c ( Z ) = {[ {z}_{11} {z}_{21} … {z}_{r 1} {z}_{12} {z}_{22} … {z}_{r 2} … {z}_{1 t} {z}_{2 t} … {z}_{rt} ]}^{T}$$

where the superscript T denotes transpose operation.

The functioning of the vec operator when applied to vectors is as follows. When vec is applied to a column vector, vec does not change the column vector in any manner. Thus, vec is an identity operation when applied to a column vector. When vec is applied over a row vector, it effectively transposes the row vector into a column vector.

For single-term least-squares KRF or KRPA of a vector c∈ [symbol] ^{n×1}, the input to the algorithm is Vector c∈ [symbol] ^{n×1}, n₁, n₂, where n₁, n₂ are integers and n=n₁n₂, and the output of the algorithm is KR factor vectors a∈ [symbol] ⁿ^{₁}^{×1}, b∈ [symbol] ⁿ^{₂}^{×1}.

In one or more implementations the algorithm for single-term least squares KRF or single-term KRPA is described below with acts (A), (B), (C), and (D), and is also referred to as Algorithm 1.
(A). Write or visualize c as a vector consisting of n₁ blocks, where the dimension of each block is n₂×1. Let

$${c}_{i}^{b} ,$$

1≤i≤n₁, is the i^{th} block of vector c, where,

$${c}_{i}^{b} = {c}_{( i - 1 ) {n}_{2} + 1 : i {n}_{2}}$$

Thus, each block

$${c}_{i}^{b} ,$$

1≤i≤n₁, in vector c is a vector of size n₂×1 with its elements given by the above equation.
(B). Obtain matrix \tilde{C}∈ [symbol] ⁿ^{₁}^{×n}^{₂}, as shown below:

$$\tilde{C} = [ \begin{matrix}v e {c ( {c}_{1}^{b} )}^{T} \\ ⋮ \\ v e {c ( {c}_{{n}_{1}}^{b} )}^{T}\end{matrix} ] ∈ {ℝ}^{{n}_{1} \times {n}_{2}}$$

(C). Perform singular value decomposition (SVD) on the matrix \tilde{C}

$$S V D ( \tilde{C} ) = U \sum {V}^{*}$$

where U is a size n₁×n₁ unitary matrix and V is a size n₂×n₂ unitary matrix including left and right singular vectors, respectively, of \tilde{C} and Σ is a diagonal matrix of size n₁×n₂ where Σᵢᵢ=σᵢ, 1≤i≤R, are the singular values of \tilde{C}, where σ₁≥σ₂≥ . . . ≥σ_{R} and R=min(n₁, n₂).
(D). Compute KR factor vectors a, b as

$$a = \sqrt{{σ}_{1}} {U}_{: , 1} and b = \sqrt{{σ}_{1}} {V}_{: , 1} \qquad ( 2 )$$

It should be noted that the Algorithm 1, described above, works even when vector c consists of complex-valued elements.

It should also be noted that, in some examples, the factorization of c into factor vectors a and b may be performed using the KPD algorithm. The KPD algorithm decomposes a given real-valued matrix into two matrices of lower dimensions. When the KPD algorithm is applied for decomposing a real-valued vector (instead of a matrix), then the resulting algorithm is similar to the KRF Algorithm 1 described above. Accordingly, when the vector c is a real-valued vector, factorization of c can also be performed through the KPD algorithm by applying it to the given real-valued column vector rather than to a matrix. Additionally or alternatively, a given complex-valued vector can be factorized using the KPD algorithm by first converting the complex-valued vector into a real-valued vector through a one-to-one mapping and then applying the KPD algorithm.

With respect to multi-term KRF, a vector c can be expressed as a summation of multiple terms, where each term consists of a KR product of two vectors, which is referred to multi-term KR factorization of vector c. Formally, multi-term KRF of a vector c can be expressed as

$$c = {\sum }_{k = 1}^{K} {a}^{( k )} ◇ {b}^{( k )} \qquad ( 3 )$$

where a^{(k)}∈ [symbol] ⁿ^{₁}^{×1}, b^{(k)}∈ [symbol] ⁿ^{₂}^{×1} for 1≤k≤K. It should be noted that the dimensions of KR factor vectors a^{(k)} and b^{(k)} remain the same in all the terms. The multi-term KRF determines the vectors a^{(k)} and b^{(k)} such that

$${\sum }_{k = 1}^{K} {a}^{( k )} ♢ {b}^{( k )}$$

is a close approximation of c in the least-squares sense or, equivalently,

$${\sum }_{k = 1}^{K} {a}^{( k )} ♢ {b}^{( k )}$$

in a close approximation of c with Euclidean distance as the metric.

For example, c=a⁽¹⁾⋄b⁽¹⁾+a⁽²⁾⋄b⁽²⁾, where a⁽¹⁾ and a⁽²⁾ have same dimensions and b⁽¹⁾ and b⁽²⁾ have same dimensions.

Following the same procedure as discussed above regarding single-term least squares KRF or KRPA of a vector (e.g., Algorithm 1), the multi-term KRF can be computed by making

$${a}^{( k )} = \sqrt{{σ}_{k}} {U}_{: , k} and {b}^{( k )} = \sqrt{{σ}_{k}} {V}_{: , k} , 1 \leq k \leq K , K = R = min ( {n}_{1} , {n}_{2} ) \qquad ( 4 )$$

It should be noted that the value of R (which is equal to min(n₁, n₂)) depends on the chosen configuration of the KRF, or, equivalently, dimensions of the KR factor vectors n₁, n₂. The single-term KRF, or the single-term KRPA of c, is the result when k=1 in equation (3) and equation (4).

For multi-term KRF or KRPA of c∈ [symbol] ^{n×1}, the input to the algorithm is vector c∈ [symbol] ^{n×1}, n₁, n₂, where n₁, n₂ are integers and n=n₁n₂, and K≤min(n₁, n₂), and the output of the algorithm is KR factor vectors a^{(k)}∈ [symbol] ⁿ^{₁}^{×1}, b^{(k)}∈ [symbol] ⁿ^{₂}^{×1}, k=1, . . . , K. K refers to the number of terms or components being generated from KRF.

In one or more implementations the algorithm for multi-term KRF is described below, and is also referred to as Algorithm 2.

For each value k, perform acts (A), (B), and (C) of Algorithm 1 discussed above.

Then, compute KR factor matrices a^{(k)}, b^{(k)} as

$${a}^{( k )} = \sqrt{{σ}_{k}} {U}_{: , k} and {b}^{( k )} = \sqrt{{σ}_{k}} {V}_{: , k} , 1 \leq k \leq K$$

Accordingly, expressing a vector c as a multi-term KRF results in a better approximation of c, but at the expense of a lower amount of compression. Note that Algorithm 2, described above, works for any complex-valued vector as well, e.g., Algorithm 2 works even when vector c contains complex-valued elements.

In some examples, the factorization of c into factor vectors a^{(k)} and b^{(k)} may be performed using the KPD algorithm. If the algorithm for multi-term KPD of real-valued matrices (where a given matrix is decomposed into multiple terms and each term contains two lower-dimensional matrices) is used for multi-term decomposition of a real-valued vector, then the resulting algorithm would be similar to Algorithm 2 described above. Accordingly, the factorization of a real-valued vector c into multiple terms with each term including two factor vectors and where the reconstructed vector from the factor vectors is close to the original vector in a least square sense (or, equivalently, in Euclidean distance) can also be performed through the multi-term KPD algorithm. Additionally or alternatively, a given complex-valued vector can be factorized using the KPD algorithm by first converting the complex-valued vector into a real-valued vector through a one-to-one mapping and then applying the KPD algorithm.

With respect to multi-term KRF with flexible dimensions for KR factor matrices, a multi-term KRF where the dimensions of the KR factor matrices in each term need not be the same, e.g.,

$${a}^{( k )} ∈ {ℝ}^{{r}_{1}^{( k )} \times {t}_{1}^{( k )}} , {b}^{( k )} ∈ {ℝ}^{{r}_{2}^{( k )} \times {t}_{2}^{( k )}} ,$$

k=1, . . . , K, and, importantly,

$${r}_{1}^{( k )}$$

need not be equal to

$${r}_{1}^{( {k}^{′} )}$$

when k≠k′ and

$${t}_{1}^{( k )}$$

need not be equal to

$${t}_{1}^{( {k}^{′} )}$$

when k≠k′ is considered. Thus, dimensions of a^{(k)} can be different from the dimensions of a^{(k′)} and dimensions of b^{(k)} can be different from the dimensions of b^{(k′)} for k≠k′. Formally, such a multi-term KRF of a vector c∈ [symbol] ^{n×1} can be expressed as follows:

$$c = {\sum }_{k = 1}^{K} {a}^{( k )} ◇ {b}^{( k )} \qquad ( 5 )$$

where

$${a}^{( k )} ∈ {ℝ}^{{n}_{1}^{( k )} \times 1} , {b}^{( k )} ∈ {ℝ}^{{n}_{2}^{( k )} \times 1} and {n}_{1}^{( k )} {n}_{2}^{( k )} = n ,$$

for 1≤k≤K. For example, c=a⁽¹⁾⋄b⁽¹⁾+a⁽²⁾⋄b⁽²⁾, where a⁽¹⁾ and a⁽²⁾ have different dimensions and b⁽¹⁾ and b⁽²⁾ have different dimensions.

It should be noted that the multi-term KRF with flexible dimensions for KR factor matrices determines the vectors a^{(k)} and b^{(k)} such that

$${\sum }_{k = 1}^{K} {a}^{( k )} ♢ {b}^{( k )}$$

is a close approximation of c in the least-squares sense or, equivalently,

$${\sum }_{k = 1}^{K} {a}^{( k )} ♢ {b}^{( k )}$$

is a close approximation of c with Euclidean distance as the metric.

It should also be noted that there is an additional flexibility in such a multi-term KRF compared to the one discussed above: The KR factor matrices can have different dimensions in each term. Such a KRF can be useful depending on the vector c for which the KRF is computed.

In one or more implementations the algorithm for such a flexible multi-term KRF is described below, and is also referred to as Algorithm 3. Algorithm 3 is an iterative algorithm using Algorithm 1.

For multi-term KRF of vector c∈ [symbol] ^{n×1} with flexible dimensions for KR factor matrices, the input is vector c∈ [symbol] ^{n×1},

$${n}_{1}^{( k )} , {n}_{2}^{{( k )}_{}} ,$$

k=1, . . . , K, where

$${n}_{1}^{( k )} , {n}_{2}^{( k )}$$

are integers such that

$${n}_{1}^{( k )} {n}_{2}^{( k )} = n for 1 \leq k \leq K ,$$

and the output is KR factor matrices

$${a}^{( k )} ∈ {ℝ}^{{n}_{1}^{( k )} \times 1} , {b}^{( k )} ∈ {ℝ}^{{n}_{2}^{( k )} \times 1} ,$$

k=1, . . . , K.

The algorithm or procedure is:

```
  for k = 1 → K
    $Using Algorithm 1 with inputs c ∈ {ℝ}^{n \times 1} , {n}_{1}^{( k )} , {n}_{2}^{( k )} , perform single - term KRF of$
    vector c
    $Algorithm 1 returns KR factor matrices a ∈ {ℝ}^{{n}_{1}^{( k )} \times 1} and b ∈ {ℝ}^{{n}_{2}^{( k )} \times 1}$
    Set a^{(k)} = a and b^{(k)} = b
    Set c = c − a^{(k)} [symbol]  b^{(k)}
  end
```

It should be noted that Algorithm 3, described above, is applicable even when vector c consists of complex-valued elements.

In one or more implementations, Algorithm 3 stops if an error value is less than an error threshold or K number of components have been computed. The error value can be computed in various manners. In one or more implementations, the vector c is factorized into two factor vectors a⁽¹⁾ and b⁽¹⁾. Then a check is made as to whether it is acceptable to have just these two factor vectors by computing e=c−a⁽¹⁾⋄b⁽¹⁾. Thus, e is the error vector when just the two factor vectors are factorized. A function of the error vector is computed (e.g., ∥e∥_{F}, the Frobenius norm of error vector e, is computed) to obtain the error value. If the error value is below the error threshold, then factorization is stopped. Otherwise, the next set of factors a⁽²⁾ and b⁽²⁾ are computed.

It should also be noted that in some examples, the factorization of c into factor vectors a^{(k)} and b^{(k)} may be performed using the KPD algorithm. When the multi-term KPD with flexible dimensions is applied for real-valued matrices (where we decompose a given matrix into multiple terms and each term contains two lower-dimensional matrices) and used for multi-term decomposition of a real-valued vector, then the resulting algorithm is similar to Algorithm 3 described above. Additionally or alternatively, a given complex-valued vector can be factorized using the KPD algorithm by first converting the complex-valued vector into a real-valued vector through a one-to-one mapping and then applying the KPD algorithm.

The techniques discussed herein can be employed in practice in a variety of different manners, examples of which are discussed below. Use of multi-level compression of feature vectors is also discussed below.

In one or more implementations, factor vectors are transmitted and a full-length vector is reconstructed. When the singular, eigen, or precoding vector is computed by a wireless device (e.g., a UE or network entity), the singular, eigen, or precoding vector is factorized as discussed above. After the factorization of the singular, eigen, or precoding vector, there are K≥1 terms (or, equivalently, components), with each term or component including two factor vectors. For example, let K=2 and the singular, eigen, or precoding vector c is factorized into two components, the first component consisting of factor vectors a⁽¹⁾, b⁽¹⁾ and the second component consisting of two factor vectors a⁽²⁾, b⁽²⁾. These factor vectors are transmitted to the other wireless device (e.g., a network entity or UE).

Feedback of factor vectors may be done in any of various manners. In one or more implementations, each factor vector is quantized using a vector quantizer or a scalar quantizer. In the case of vector quantization, each factor vector is mapped to a vector or codeword in a codebook and the corresponding index of the codebook and the index of the codeword are sent to the other wireless device. The mapping of a factor vector to a vector or codeword in a codebook is known at both the wireless devices (e.g., through communication between the devices or through prior information available at both the devices). Thus, when the other device receives the index of the codeword and the codebook, it de-maps the received indices to obtain the corresponding vectors. This procedure of mapping the factor vectors into codebook and codewords indices may also be referred to as quantization and the reverse procedure of determining the vectors corresponding to the received indices at the other wireless device may be referred to dequantization.

Additionally or alternatively, when a factor vector is quantized using scalar quantization, each element of a factor vector is quantized using a scalar quantizer. Each quantized element of the factor vector is then converted into bits and then to channel symbols and sent over the channel. At the other wireless device, the elements of the received factor vector are the ones that are scalar quantized at the first wireless device.

Additionally or alternatively, the factor vectors corresponding to a singular, eigen, or precoding vector may be associated with a Precoding Matrix Indicator (PMI) value. For example, a set of compressed singular, eigen, or precoding vectors (e.g., factor vectors) are derived, where each compressed singular, eigen, or precoding vector (e.g., each factor vector) corresponds to a distinct layer of the PMI.

Additionally or alternatively, the set of compressed singular, eigen, or precoding vectors (e.g., factor vectors) are fed back as part of a CSI report including CSI, beam information, or a combination thereof.

Additionally or alternatively, the factor vectors are compressed through an AI/ML model before transmission over the wireless channel. An AI/ML model can compress the factor vectors, generating a low-dimensional vector (lower than the dimensions of the factor vector given at its input). Compressed factor vectors are transmitted over the wireless channel resulting in lower signaling overhead. At the other device (e.g., the network entity), the compressed factor vectors are decompressed or reconstructed using another AI/ML model.

Once the factor vectors in all the components, e.g., a⁽¹⁾, b⁽¹⁾, a⁽²⁾, b⁽²⁾ in this example, are transmitted from the wireless device (e.g., the UE considering CSI feedback for downlink communication) and received at the other wireless device (e.g., the network entity considering CSI feedback for downlink communication) the full-length singular, eigen, or precoding vector ĉ is reconstructed, where ĉ=a⁽¹⁾⋄b⁽¹⁾+a⁽²⁾⋄b⁽²⁾.

The discussion above describes compressing a feature vector based on a column-wise KR product (also known as a column-wise matrix direct product or a column-wise KR product). For example, assume that a feature vector c of length-n has been factorized into two factor vectors a and b, having length n₁ and n₂, respectively, where n=n₁n₂. This factorization would result in a compression from n₁n₂ elements to n₁+n₂ elements, which can be called a first level of compression.

The factor vector a can further be factorized into two factor vectors d and e, having length l₁ and l₂, respectively, where l₁l₂=n₁. By transmitting or feeding back vectors d, e and b, the vector a can be reconstructed from the column-wise KR product of d and e and then vector c can be reconstructed through column-wise KR product of a and b. Compared to the first level of compression, this technique of further or a second level of factorizing or compressing vector a would reduce the feedback from n₁+n₂ elements to l₁+l₂+n₂ and, as n₁=l₁l₂, l₁+l₂+n₂≤n₁+n₂. In a similar manner, vector b can further be factorized into two vectors each having a smaller length than n₂, resulting in more compression and further reduction in the feedback.

The multi-level compression, as outlined above, can increase the amount of compression, but it would also typically increase ∥c−ĉ∥_{F}, where ĉ is the reconstructed vector from the factor vectors. Thus, the compressing the singular, eigen, or precoding vectors and the extending it to multi-level compression allows a trade-off between the amount of compression and desired accuracy of the reconstructed singular, eigen, or precoding vector.

In one or more implementations, the error between the original vector and the vector reconstructed from the factor vectors, ∥ĉ−c∥_{F}, depends on the chosen configuration (e.g., the number of terms and the lengths of the factor vectors in each term) of the KRF. The error can be lowered by one or both of considering a higher number of terms or by adjusting the lengths of the factor vectors. However, reducing the error results in lower compression and increased signaling overhead in transmitting the factor vectors. Another technique for of reducing the error without increasing the number of terms in the factorization is as follows.

Consider single-term KRF of a given singular, eigen, or precoding vector c into two factor vectors a and b, and transmitting a and b towards the other wireless device (e.g., where a decoder NN is located). The error vector c−ĉ is computed, where ĉ=a⋄b, and for convenience let c−ĉ=cₑ. The L≥1 largest elements of the error vector cₑ are found and the corresponding L element values of the error vector cₑ are transmitted along with the indices of those elements (e.g., information on their location in cₑ) to the other wireless device. Thus, in addition to the two factor vectors a and b, these L largest elements of the error vector are also transmitted to the other wireless device.

At the other wireless device, while reconstructing the full-length singular, eigen, or precoding vector (e.g., at the input of the decoder), a⋄b=ĉ is first computed. Then to the vector ĉ the L elements of cₑ are added to appropriate elements of ĉ as per the indices of the received L elements of cₑ.

In one or more implementations, when n, the length of the singular, eigen, or precoding vector, is a prime number, there are not any integer factors for n and the singular, eigen, or precoding vector cannot be factorized or compressed into factor vectors having length shorter than n. Similarly, when the value of n is an odd number, there are very few integer factors of n, compared to the case when n is an even number. In such cases, the length of the singular, eigen, or precoding vector can be extended by one unit by padding the singular, eigen, or precoding vector at the end (or at the beginning) with a zero. Thus, when the original length of the singular, eigen, or precoding vector is a prime number or an odd-valued number, then, after padding the singular, eigen, or precoding vector with a zero-valued element at the end (or at the beginning), the length of the singular, eigen, or precoding vector becomes an even number and there are multiple options for choosing the lengths of the factor vectors. When the full-length singular, eigen, or precoding vector is reconstructed at the input of the decoder NN at the other wireless device, the last element (or the first element) of the reconstructed singular, eigen, or precoding vector is omitted or deleted before giving it to the decoder NN.

Accordingly, methods or techniques for lossy compression of unit norm vectors that reduces (e.g., minimizes) the loss in cosine similarity is discussed herein.

Furthermore, the methods or techniques can be used as a stand-alone method or technique, or jointly with other methods or techniques for achieving compression of channel singular vectors, eigen vectors, or precoding vectors. The compressed singular, eigen, or precoding vectors can further be quantized thereby not losing the benefits of compression through quantization.

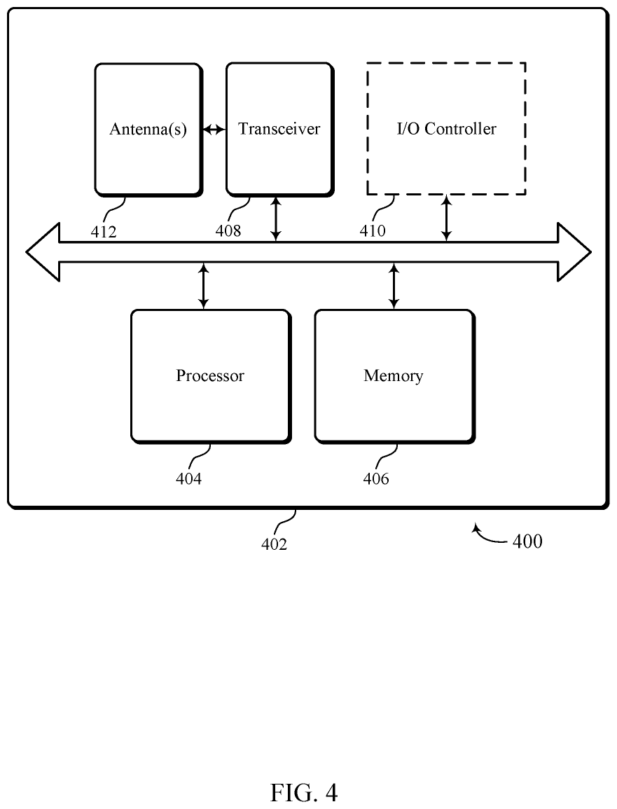

FIG. 4 illustrates an example of a block diagram 400 of a device 402 that supports vector compression based on satisfying a metric in accordance with aspects of the present disclosure. The device 402 may be an example of a UE 104 as described herein. The device 402 may support wireless communication with one or more network entities 102, UEs 104, or any combination thereof. The device 402 may include components for bi-directional communications including components for transmitting and receiving communications, such as a processor 404, a memory 406, a transceiver 408, and an I/O controller 410. These components may be in electronic communication or otherwise coupled (e.g., operatively, communicatively, functionally, electronically, electrically) via one or more interfaces (e.g., buses).

The processor 404, the memory 406, the transceiver 408, or various combinations thereof or various components thereof may be examples of means for performing various aspects of the present disclosure as described herein. For example, the processor 404, the memory 406, the transceiver 408, or various combinations or components thereof may support a method for performing one or more of the operations described herein.

In some implementations, the processor 404, the memory 406, the transceiver 408, or various combinations or components thereof may be implemented in hardware (e.g., in communications management circuitry). The hardware may include a processor, a digital signal processor (DSP), an application-specific integrated circuit (ASIC), a field-programmable gate array (FPGA) or other programmable logic device, a discrete gate or transistor logic, discrete hardware components, or any combination thereof configured as or otherwise supporting a means for performing the functions described in the present disclosure. In some implementations, the processor 404 and the memory 406 coupled with the processor 404 may be configured to perform one or more of the functions described herein (e.g., executing, by the processor 404, instructions stored in the memory 406).

For example, the processor 404 may support wireless communication at the device 402 in accordance with examples as disclosed herein. Processor 404 may be configured as or otherwise support to: factorize, based on Khatri-Rao factorization and so that a metric is satisfied, at least one information vector into one or more components where each component includes a first factor vector and a second factor vector, and each of the first factor vector and the second factor vector has fewer elements than the information vector, and the at least one information vector has unit Euclidean length and includes a set of information parameters; generate encoded information by encoding at least the first factor vector or the second factor vector in at least one of the components; and transmit, to a first device, a first signaling indicating the encoded information.

Additionally or alternatively, the processor 404 may be configured to or otherwise support: where the first factor vector is a first column vector, the second factor vector is a second column vector, and the information vector is a column vector; where the set of information parameters are based on channel state information; where the processor is configured to cause the apparatus to: receive, from the first device, at least one reference signal; and generate channel state information based on the received at least one reference signal; where the channel state information includes a characterization of a channel matrix that includes at least one of one or more singular vectors of the channel matrix, one or more eigen vectors of the channel matrix, one or more eigen vectors of a channel covariance matrix, or one or more precoding vectors; where the processor is configured to cause the apparatus to determine the information parameters of the set of information parameters are based on distinct attributes extracted by an artificial intelligence or machine learning model; where the processor is configured to cause the apparatus to determine the information parameters of the set of information parameters based on signaling from a second device that is different than the first device; where the processor is configured to cause the apparatus to map the information vector to obtain a real-valued information vector using a mapping that is a one-to-one mapping known at the first device; where to generate the encoded information is to determine at least one quantized representation of at least the first factor vector or the second factor vector in at least one of the one or more components based on at least one of a scalar quantization or a vector quantization scheme; where to generate the encoded information is to encode at least the first factor vector or the second factor vector in at least one of the one or more components in a form of at least one index corresponding to one or more codebooks; where the one or more codebooks correspond to at least one of a spatial transformation, a frequency transformation, and a time domain transformation; where to generate the encoded information is to obtain a latent representation of at least the first factor vector or the second factor vector in at least one of the one or more components using an artificial intelligence or machine learning model; where to generate the encoded information is to bit encode at least the first factor vector or the second factor vector in at least one of the one or more components; where the apparatus determines a number of components into which the information vector is factorized; where the processor is configured to cause the apparatus to transmit, to the first device, a second signaling indicating a number of components into which the information vector is factorized; where the processor is configured to cause the apparatus to: receive, from the first device or a second device other than the first device, a second signaling; and determine, based on the second signaling, a number of components into which the information vector is factorized; where the apparatus determines a length of the first factor vector and the second factor vector in each of the one or more components; where the processor is configured to cause the apparatus to transmit, to the first device, a second signaling indicating a length of the first factor vector and the second factor vector in each of the one or more components; where the processor is configured to cause the apparatus to receive, from the first device or a second device other than the first device, a second signaling indicating a length of the first factor vector and the second factor vector in each of the one or more components; where the processor is configured to cause the apparatus to determine the one or more components based on an error threshold; where the processor is configured to cause the apparatus to: determine an error threshold based on a message signal received from the first device or a second device other than the first device; and determine the one or more components based on the received error threshold; where the processor is configured to cause the apparatus to: factorize, based on Khatri-Rao factorization, the first factor vector into one or more additional components that each include a third factor vector and a fourth factor vector; and generate the encoded information by encoding at least the third factor vector or the fourth factor vector in at least one of the one or more additional components; where the processor is configured to cause the apparatus to: determine an error vector indicating an error between the at least one information vector and a Khatri-Rao product of the first factor vector and the second factor vector; select a particular number of largest elements of the error vector; and include, in the first signaling, an indication of both the particular number of largest elements of the error vector and positions of the particular number of largest elements in the error vector; where a number of the one or more components is greater than one and a length of the first factor vector in a first component of the one or more components is different from the length of the first factor vector in a second component of the one or more components, and where the processor is configured to cause the apparatus to perform a factorization process to determine the first factor vector and the second factor vector in a particular component by: dividing the information vector into a first number of vectors each having a first length, where the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; multiplying the first factor vector with the highest singular value or multiplying the second factor vector with the highest singular value, or multiplying the first factor vector and the second factor vector each with a square root of the highest singular value; computing an error vector by subtracting a column-wise Khatri-Rao product of the first factor vector of the first component with the second factor vector of the first component from the information vector; computing a value of a function of the error vector to determine an error value; stopping the factorization process if the error value is less than an error threshold or a number of components have been computed; and replacing, if the error value is greater than the error threshold or if less than the number of components have been computed, the information vector with the error vector and repeating the factorization process; where the first factor vector has a same dimension in each of the one or more components, the second factor vector has a same dimension in each of the one or more components, and the processor is configured to cause the apparatus to determine, for each component, the first factor vector and the second factor vector by: dividing the information vector into a first number of vectors each having a first length where the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; and multiplying the first factor vector in the first component with the highest singular value or multiplying the second factor vector in the first component with the highest singular value or multiplying the first factor vector and the second factor vector each, in the first component, with a square root of the highest singular value; where a number of components and lengths of factor vectors in each of the one or more components are determined by a machine learning model; where the metric is cosine similarity or cosine distance.

For example, the processor 404 may support wireless communication at the device 402 in accordance with examples as disclosed herein. Processor 404 may be configured as or otherwise support a means for factorizing, based on Khatri-Rao factorization and so that a metric is satisfied, at least one information vector into one or more components where each component includes a first factor vector and a second factor vector, and each of the first factor vector and the second factor vector has fewer elements than the information vector, and the at least one information vector has unit Euclidean length and includes a set of information parameters; generating encoded information by encoding at least the first factor vector or the second factor vector in at least one of the components; and transmitting, to a first device, a first signaling indicating the encoded information.

Additionally or alternatively, the processor 404 may be configured to or otherwise support: where the first factor vector is a first column vector, the second factor vector is a second column vector, and the information vector is a column vector; where the set of information parameters are based on channel state information; further including: receiving, from the first device, at least one reference signal; and generating channel state information based on the received at least one reference signal; where the channel state information includes a characterization of a channel matrix that includes at least one of one or more singular vectors of the channel matrix, one or more eigen vectors of the channel matrix, one or more eigen vectors of a channel covariance matrix, or one or more precoding vectors; further including determining the information parameters of the set of information parameters are based on distinct attributes extracted by an artificial intelligence or machine learning model; further including determining the information parameters of the set of information parameters based on signaling from a second device that is different than the first device; further including mapping the information vector to obtain a real-valued information vector using a mapping that is a one-to-one mapping known at the first device; where generating the encoded information includes determining at least one quantized representation of at least the first factor vector or the second factor vector in at least one of the one or more components based on at least one of a scalar quantization or a vector quantization scheme; where generating the encoded information includes encoding at least the first factor vector or the second factor vector in at least one of the one or more components in a form of at least one index corresponding to one or more codebooks; where the one or more codebooks correspond to at least one of a spatial transformation, a frequency transformation, and a time domain transformation; where generating the encoded information includes obtaining a latent representation of at least the first factor vector or the second factor vector in at least one of the one or more components using an artificial intelligence or machine learning model; where generating the encoded information is includes bit encoding at least the first factor vector or the second factor vector in at least one of the one or more components; where an apparatus implementing the method determines a number of components into which the information vector is factorized; further including transmitting, to the first device, a second signaling indicating a number of components into which the information vector is factorized; further including: receiving, from the first device or a second device other than the first device, a second signaling; and determining, based on the second signaling, a number of components into which the information vector is factorized; where an apparatus implementing the method determines a length of the first factor vector and the second factor vector in each of the one or more components; further including transmitting, to the first device, a second signaling indicating a length of the first factor vector and the second factor vector in each of the one or more components; further including to receiving, from the first device or a second device other than the first device, a second signaling indicating a length of the first factor vector and the second factor vector in each of the one or more components; further including determining the one or more components based on an error threshold; further including: determining an error threshold based on a message signal received from the first device or a second device other than the first device; and determining the one or more components based on the received error threshold; further including: factorizing, based on Khatri-Rao factorization, the first factor vector into one or more additional components that each include a third factor vector and a fourth factor vector; and generating the encoded information by encoding at least the third factor vector or the fourth factor vector in at least one of the one or more additional components; further including: determining an error vector indicating an error between the at least one information vector and a Khatri-Rao product of the first factor vector and the second factor vector; selecting a particular number of largest elements of the error vector; and including, in the first signaling, an indication of both the particular number of largest elements of the error vector and positions of the particular number of largest elements in the error vector; where a number of the one or more components is greater than one and a length of the first factor vector in a first component of the one or more components is different from the length of the first factor vector in a second component of the one or more components, and further including performing a factorization process to determine the first factor vector and the second factor vector in a particular component by: dividing the information vector into a first number of vectors each having a first length, where the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; multiplying the first factor vector with the highest singular value or multiplying the second factor vector with the highest singular value, or multiplying the first factor vector and the second factor vector each with a square root of the highest singular value; computing an error vector by subtracting a column-wise Khatri-Rao product of the first factor vector of the first component with the second factor vector of the first component from the information vector; computing a value of a function of the error vector to determine an error value; stopping the factorization process if the error value is less than an error threshold or a number of components have been computed; and replacing, if the error value is greater than the error threshold or if less than the number of components have been computed, the information vector with the error vector and repeating the factorization process; where the first factor vector has a same dimension in each of the one or more components, the second factor vector has a same dimension in each of the one or more components, and further including determining, for each component, the first factor vector and the second factor vector by: dividing the information vector into a first number of vectors each having a first length where the first length is smaller than the length of the information vector; reshaping the information vector into a matrix of a first size using the first number of vectors each having the first length; computing a singular value decomposition of the matrix and determining left singular vectors of the matrix, right singular vectors of the matrix, and singular values of the matrix; computing the first factor vector in the first component as the left singular vector corresponding to a highest singular value; computing the second factor vector in the first component as the right singular vector corresponding to the highest singular value; and multiplying the first factor vector in the first component with the highest singular value or multiplying the second factor vector in the first component with the highest singular value or multiplying the first factor vector and the second factor vector each, in the first component, with a square root of the highest singular value; where a number of components and lengths of factor vectors in each of the one or more components are determined by a machine learning model; where the metric is cosine similarity or cosine distance.

The processor 404 of the device 402, such as a UE 104, may support wireless communication in accordance with examples as disclosed herein. The processor 404 includes at least one controller coupled with at least one memory, and is configured to or operable to cause the processor to factorize, based on Khatri-Rao factorization and so that a metric is satisfied, at least one information vector into one or more components wherein each component comprises of a first factor vector and a second factor vector, and each of the first factor vector and the second factor vector has fewer elements than the information vector, and the at least one information vector has unit Euclidean length and includes a set of information parameters; generate encoded information by encoding at least the first factor vector or the second factor vector in at least one of the components; and transmit, to a first device, a first signaling indicating the encoded information.

The processor 404 of the device 402, such as a UE 104, may support wireless communication in accordance with examples as disclosed herein. The processor 404 includes at least one controller coupled with at least one memory, and is configured to or operable to cause the processor to receive, from a first device, a first signaling indicating a set of information and a set of parameters, wherein the set of information comprises at least one set of components wherein each component includes an encoded first factor vector and an encoded second factor vector and wherein each set of components corresponds to an information vector; decode the encoded first factor vector and the encoded second factor vector; generate a Khatri-Rao product of the first factor vector and the second factor vector corresponding to each of the components; and reconstruct an information vector by adding the Khatri-Rao products corresponding to each of the components.

The processor 404 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some implementations, the processor 404 may be configured to operate a memory array using a memory controller. In some other implementations, a memory controller may be integrated into the processor 404. The processor 404 may be configured to execute computer-readable instructions stored in a memory (e.g., the memory 406) to cause the device 402 to perform various functions of the present disclosure.

The memory 406 may include random access memory (RAM) and read-only memory (ROM). The memory 406 may store computer-readable, computer-executable code including instructions that, when executed by the processor 404 cause the device 402 to perform various functions described herein. The code may be stored in a non-transitory computer-readable medium such as system memory or another type of memory. In some implementations, the code may not be directly executable by the processor 404 but may cause a computer (e.g., when compiled and executed) to perform functions described herein. In some implementations, the memory 406 may include, among other things, a basic I/O system (BIOS) which may control basic hardware or software operation such as the interaction with peripheral components or devices.

The I/O controller 410 may manage input and output signals for the device 402. The I/O controller 410 may also manage peripherals not integrated into the device 402. In some implementations, the I/O controller 410 may represent a physical connection or port to an external peripheral. In some implementations, the I/O controller 410 may utilize an operating system such as iOS®, ANDROID®, MS-DOS®, MS-WINDOWS®, OS/2®, UNIX®, LINUX®, or another known operating system. In some implementations, the I/O controller 410 may be implemented as part of a processor, such as the processor 404. In some implementations, a user may interact with the device 402 via the I/O controller 410 or via hardware components controlled by the I/O controller 410.

In some implementations, the device 402 may include a single antenna 412. However, in some other implementations, the device 402 may have more than one antenna 412 (i.e., multiple antennas), including multiple antenna panels or antenna arrays, which may be capable of concurrently transmitting or receiving multiple wireless transmissions. The transceiver 408 may communicate bi-directionally, via the one or more antennas 412, wired, or wireless links as described herein. For example, the transceiver 408 may represent a wireless transceiver and may communicate bi-directionally with another wireless transceiver. The transceiver 408 may also include a modem to modulate the packets, to provide the modulated packets to one or more antennas 412 for transmission, and to demodulate packets received from the one or more antennas 412.

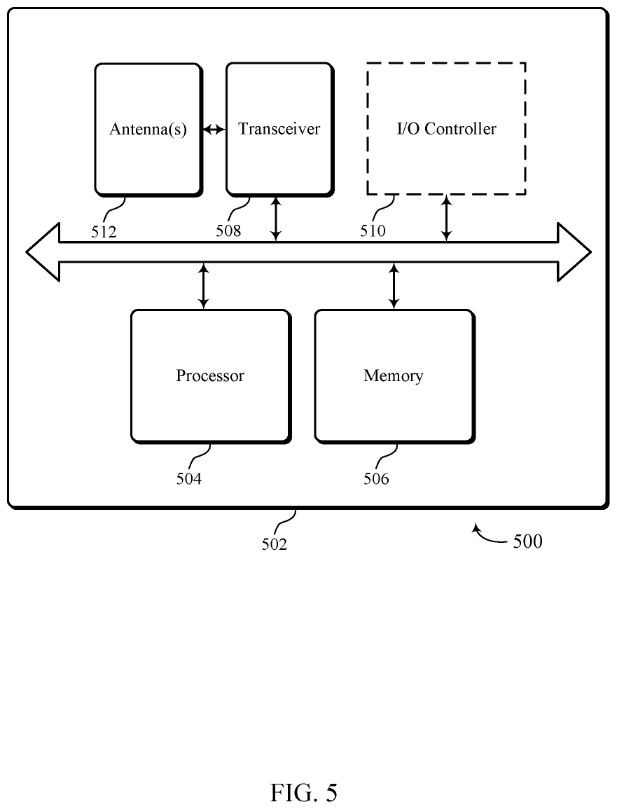

FIG. 5 illustrates an example of a block diagram 500 of a device 502 that supports vector compression based on satisfying a metric in accordance with aspects of the present disclosure. The device 502 may be an example of a network entity 102 as described herein. The device 502 may support wireless communication with one or more network entities 102, UEs 104, or any combination thereof. The device 502 may include components for bi-directional communications including components for transmitting and receiving communications, such as a processor 504, a memory 506, a transceiver 508, and an I/O controller 510. These components may be in electronic communication or otherwise coupled (e.g., operatively, communicatively, functionally, electronically, electrically) via one or more interfaces (e.g., buses).

The processor 504, the memory 506, the transceiver 508, or various combinations thereof or various components thereof may be examples of means for performing various aspects of the present disclosure as described herein. For example, the processor 504, the memory 506, the transceiver 508, or various combinations or components thereof may support a method for performing one or more of the operations described herein.

In some implementations, the processor 504, the memory 506, the transceiver 508, or various combinations or components thereof may be implemented in hardware (e.g., in communications management circuitry). The hardware may include a processor, a digital signal processor (DSP), an application-specific integrated circuit (ASIC), a field-programmable gate array (FPGA) or other programmable logic device, a discrete gate or transistor logic, discrete hardware components, or any combination thereof configured as or otherwise supporting a means for performing the functions described in the present disclosure. In some implementations, the processor 504 and the memory 506 coupled with the processor 504 may be configured to perform one or more of the functions described herein (e.g., executing, by the processor 504, instructions stored in the memory 506).

For example, the processor 504 may support wireless communication at the device 502 in accordance with examples as disclosed herein. Processor 504 may be configured as or otherwise support to: receive, from a first device, a first signaling indicating a set of information and a set of parameters, where the set of information includes at least one set of components where each component includes an encoded first factor vector and an encoded second factor vector and where each set of components corresponds to an information vector; decode the encoded first factor vector and the encoded second factor vector; generate a Khatri-Rao product of the first factor vector and the second factor vector corresponding to each of the components; and reconstruct an information vector by adding the Khatri-Rao products corresponding to each of the components.

Additionally or alternatively, the processor 504 may be configured to or otherwise support: where the set of parameters includes one or more of information indicating a number of components of at least one set of components, or dimensions of the encoded first and second factor vectors in each component of at least one set of components, and where encoding performed at the first device includes at least one of a quantization codebook associated with at least one vector dequantization or de-mapping scheme; where the processor is configured to cause the apparatus to determine the first set of parameters based on one or more of a predefined value or an indication received from the first device or a different device than the first device; where the first factor vector is a first column vector, the second factor vector is a second column vector, and the information vector is a column vector; where the processor is configured to cause the apparatus to decode at least the first factor vector or the second factor vector in at least one of the components from at least one index corresponding to one or more codebooks; where the one or more codebooks correspond to at least one of a spatial transformation, a frequency transformation, and a time domain transformation; where the processor is configured to cause the apparatus to decode at least the first factor vector or the second factor vector in at least one of the components from a latent representation received using an artificial intelligence of a machine learning model; where the processor is configured to cause the apparatus to transmit, to the first device, a second signaling indicating a number of components into which the information vector is to be factorized; where the processor is configured to cause the apparatus to transmit, to the first device, a second signaling indicating a length of the first factor vector and the second factor vector in each of the components.

For example, the processor 504 may support wireless communication at the device 502 in accordance with examples as disclosed herein. Processor 504 may be configured as or otherwise support a means for receiving, from a first device, a first signaling indicating a set of information and a set of parameters, where the set of information includes at least one set of components where each component includes an encoded first factor vector and an encoded second factor vector and where each set of components corresponds to an information vector; decoding the encoded first factor vector and the encoded second factor vector; generating a Khatri-Rao product of the first factor vector and the second factor vector corresponding to each of the components; and reconstructing an information vector by adding the Khatri-Rao products corresponding to each of the components.

Additionally or alternatively, the processor 504 may be configured to or otherwise support: where the set of parameters includes one or more of information indicating a number of components of at least one set of components, or dimensions of the encoded first and second factor vectors in each component of at least one set of components, and where encoding performed at the first device includes at least one of a quantization codebook associated with at least one vector dequantization or de-mapping scheme; further including determining the first set of parameters based on one or more of a predefined value or an indication received from the first device or a different device than the first device; where the first factor vector is a first column vector, the second factor vector is a second column vector, and the information vector is a column vector; further including decoding at least the first factor vector or the second factor vector in at least one of the components from at least one index corresponding to one or more codebooks; where the one or more codebooks correspond to at least one of a spatial transformation, a frequency transformation, and a time domain transformation; further including decoding at least the first factor vector or the second factor vector in at least one of the components from a latent representation received using an artificial intelligence of a machine learning model; further including transmitting, to the first device, a second signaling indicating a number of components into which the information vector is to be factorized; further including transmitting, to the first device, a second signaling indicating a length of the first factor vector and the second factor vector in each of the components.

The processor 504 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some implementations, the processor 504 may be configured to operate a memory array using a memory controller. In some other implementations, a memory controller may be integrated into the processor 504. The processor 504 may be configured to execute computer-readable instructions stored in a memory (e.g., the memory 506) to cause the device 502 to perform various functions of the present disclosure.

The memory 506 may include random access memory (RAM) and read-only memory (ROM). The memory 506 may store computer-readable, computer-executable code including instructions that, when executed by the processor 504 cause the device 502 to perform various functions described herein. The code may be stored in a non-transitory computer-readable medium such as system memory or another type of memory. In some implementations, the code may not be directly executable by the processor 504 but may cause a computer (e.g., when compiled and executed) to perform functions described herein. In some implementations, the memory 506 may include, among other things, a basic I/O system (BIOS) which may control basic hardware or software operation such as the interaction with peripheral components or devices.

The I/O controller 510 may manage input and output signals for the device 502. The I/O controller 510 may also manage peripherals not integrated into the device 502. In some implementations, the I/O controller 510 may represent a physical connection or port to an external peripheral. In some implementations, the I/O controller 510 may utilize an operating system such as iOS®, ANDROID®, MS-DOS®, MS-WINDOWS®, OS/2®, UNIX®, LINUX®, or another known operating system. In some implementations, the I/O controller 510 may be implemented as part of a processor, such as the processor 504. In some implementations, a user may interact with the device 502 via the I/O controller 510 or via hardware components controlled by the I/O controller 510.

In some implementations, the device 502 may include a single antenna 512. However, in some other implementations, the device 502 may have more than one antenna 512 (i.e., multiple antennas), including multiple antenna panels or antenna arrays, which may be capable of concurrently transmitting or receiving multiple wireless transmissions. The transceiver 508 may communicate bi-directionally, via the one or more antennas 512, wired, or wireless links as described herein. For example, the transceiver 508 may represent a wireless transceiver and may communicate bi-directionally with another wireless transceiver. The transceiver 508 may also include a modem to modulate the packets, to provide the modulated packets to one or more antennas 512 for transmission, and to demodulate packets received from the one or more antennas 512.

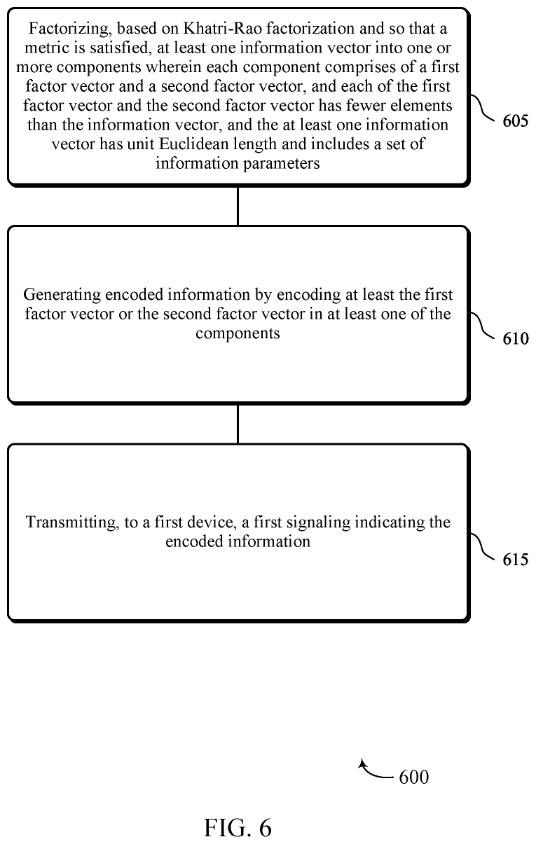

FIG. 6 illustrates a flowchart of a method 600 that supports vector compression based on satisfying a metric in accordance with aspects of the present disclosure. The operations of the method 600 may be implemented by a device or its components as described herein. For example, the operations of the method 600 may be performed by a UE 104 as described with reference to FIGS. 1 through 5. In some implementations, the device may execute a set of instructions to control the function elements of the device to perform the described functions. Additionally, or alternatively, the device may perform aspects of the described functions using special-purpose hardware.

At 605, the method may include factorizing, based on Khatri-Rao factorization and so that a metric is satisfied, at least one information vector into one or more components wherein each component comprises of a first factor vector and a second factor vector, and each of the first factor vector and the second factor vector has fewer elements than the information vector, and the at least one information vector has unit Euclidean length and includes a set of information parameters. The operations of 605 may be performed in accordance with examples as described herein. In some implementations, aspects of the operations of 605 may be performed by a device as described with reference to FIG. 1.

At 610, the method may include generating encoded information by encoding at least the first factor vector or the second factor vector in at least one of the components. The operations of 610 may be performed in accordance with examples as described herein. In some implementations, aspects of the operations of 610 may be performed by a device as described with reference to FIG. 1.

At 615, the method may include transmitting, to a first device, a first signaling indicating the encoded information. The operations of 615 may be performed in accordance with examples as described herein. In some implementations, aspects of the operations of 615 may be performed by a device as described with reference to FIG. 1.

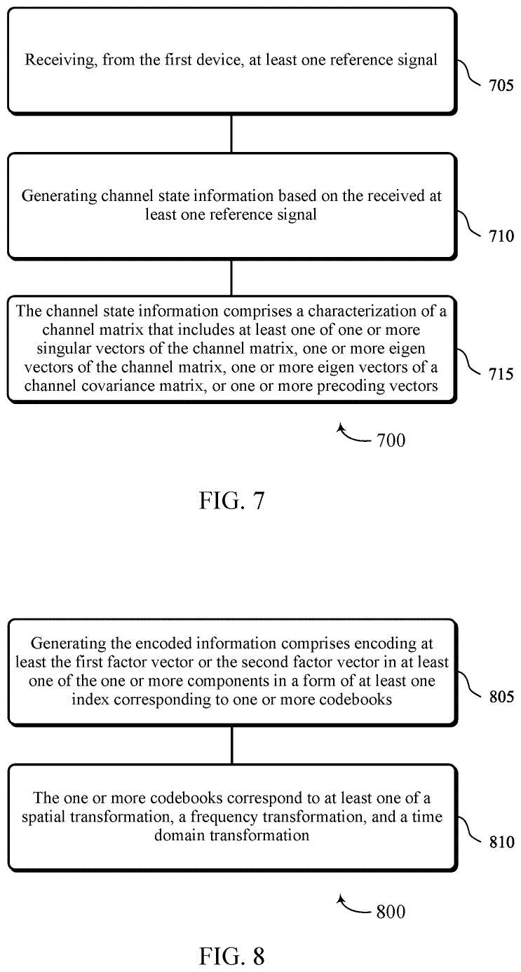

FIG. 7 illustrates a flowchart of a method 700 that supports vector compression based on satisfying a metric in accordance with aspects of the present disclosure. The operations of the method 700 may be implemented by a device or its components as described herein. For example, the operations of the method 700 may be performed by a UE 104 as described with reference to FIGS. 1 through 5. In some implementations, the device may execute a set of instructions to control the function elements of the device to perform the described functions. Additionally, or alternatively, the device may perform aspects of the described functions using special-purpose hardware.

At 705, the method may include receiving, from the first device, at least one reference signal. The operations of 705 may be performed in accordance with examples as described herein. In some implementations, aspects of the operations of 705 may be performed by a device as described with reference to FIG. 1.

At 710, the method may include generating channel state information based on the received at least one reference signal. The operations of 710 may be performed in accordance with examples as described herein. In some implementations, aspects of the operations of 710 may be performed by a device as described with reference to FIG. 1.

At 715, the method may include the channel state information comprises a characterization of a channel matrix that includes at least one of one or more singular vectors of the channel matrix, one or more eigen vectors of the channel matrix, one or more eigen vectors of a channel covariance matrix, or one or more precoding vectors. The operations of 715 may be performed in accordance with examples as described herein. In some implementations, aspects of the operations of 715 may be performed by a device as described with reference to FIG. 1.

FIG. 8 illustrates a flowchart of a method 800 that supports vector compression based on satisfying a metric in accordance with aspects of the present disclosure. The operations of the method 800 may be implemented by a device or its components as described herein. For example, the operations of the method 800 may be performed by a UE 104 as described with reference to FIGS. 1 through 5. In some implementations, the device may execute a set of instructions to control the function elements of the device to perform the described functions. Additionally, or alternatively, the device may perform aspects of the described functions using special-purpose hardware.

At 805, the method may include generating the encoded information comprises encoding at least the first factor vector or the second factor vector in at least one of the one or more components in a form of at least one index corresponding to one or more codebooks. The operations of 805 may be performed in accordance with examples as described herein. In some implementations, aspects of the operations of 805 may be performed by a device as described with reference to FIG. 1.

At 810, the method may include the one or more codebooks correspond to at least one of a spatial transformation, a frequency transformation, and a time domain transformation. The operations of 810 may be performed in accordance with examples as described herein. In some implementations, aspects of the operations of 810 may be performed by a device as described with reference to FIG. 1.

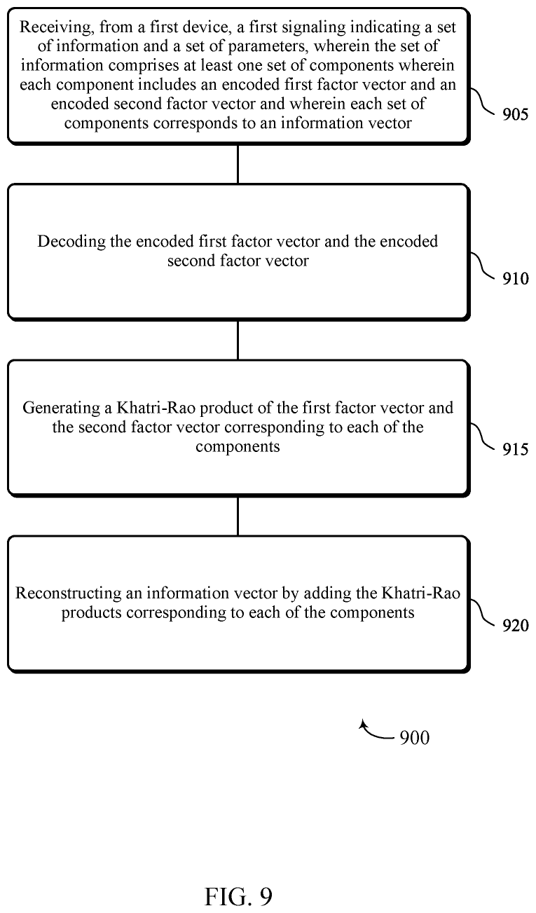

FIG. 9 illustrates a flowchart of a method 900 that supports vector compression based on satisfying a metric in accordance with aspects of the present disclosure. The operations of the method 900 may be implemented by a device or its components as described herein. For example, the operations of the method 900 may be performed by a network entity 102 as described with reference to FIGS. 1 through 5. In some implementations, the device may execute a set of instructions to control the function elements of the device to perform the described functions. Additionally, or alternatively, the device may perform aspects of the described functions using special-purpose hardware.

At 905, the method may include receiving, from a first device, a first signaling indicating a set of information and a set of parameters, wherein the set of information comprises at least one set of components wherein each component includes an encoded first factor vector and an encoded second factor vector and wherein each set of components corresponds to an information vector. The operations of 905 may be performed in accordance with examples as described herein. In some implementations, aspects of the operations of 905 may be performed by a device as described with reference to FIG. 1.

At 910, the method may include decoding the encoded first factor vector and the encoded second factor vector. The operations of 910 may be performed in accordance with examples as described herein. In some implementations, aspects of the operations of 910 may be performed by a device as described with reference to FIG. 1.

At 915, the method may include generating a Khatri-Rao product of the first factor vector and the second factor vector corresponding to each of the components. The operations of 915 may be performed in accordance with examples as described herein. In some implementations, aspects of the operations of 915 may be performed by a device as described with reference to FIG. 1.

At 920, the method may include reconstructing an information vector by adding the Khatri-Rao products corresponding to each of the components. The operations of 920 may be performed in accordance with examples as described herein. In some implementations, aspects of the operations of 920 may be performed by a device as described with reference to FIG. 1.

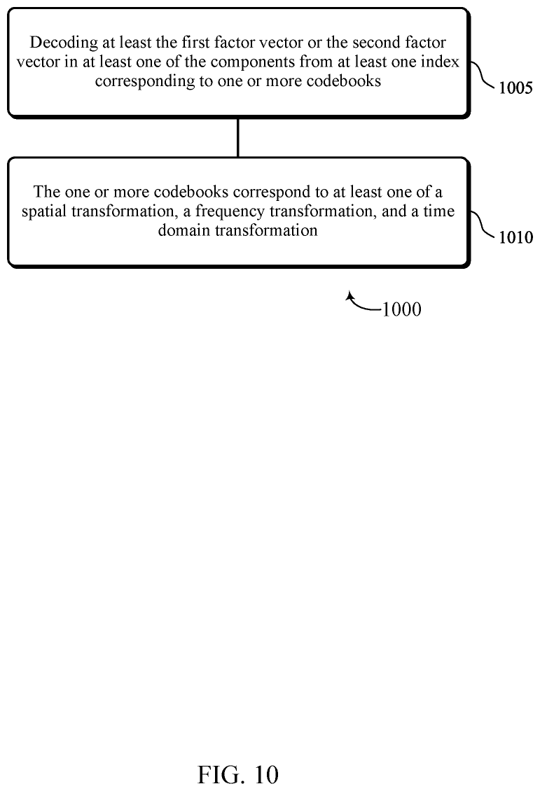

FIG. 10 illustrates a flowchart of a method 1000 that supports vector compression based on satisfying a metric in accordance with aspects of the present disclosure. The operations of the method 1000 may be implemented by a device or its components as described herein. For example, the operations of the method 1000 may be performed by a network entity 102 as described with reference to FIGS. 1 through 5. In some implementations, the device may execute a set of instructions to control the function elements of the device to perform the described functions. Additionally, or alternatively, the device may perform aspects of the described functions using special-purpose hardware.

At 1005, the method may include decoding at least the first factor vector or the second factor vector in at least one of the components from at least one index corresponding to one or more codebooks. The operations of 1005 may be performed in accordance with examples as described herein. In some implementations, aspects of the operations of 1005 may be performed by a device as described with reference to FIG. 1.

At 1010, the method may include the one or more codebooks correspond to at least one of a spatial transformation, a frequency transformation, and a time domain transformation. The operations of 1010 may be performed in accordance with examples as described herein. In some implementations, aspects of the operations of 1010 may be performed by a device as described with reference to FIG. 1.

It should be noted that the methods described herein describes possible implementations, and that the operations and the steps may be rearranged or otherwise modified and that other implementations are possible. Further, aspects from two or more of the methods may be combined.

The various illustrative blocks and components described in connection with the disclosure herein may be implemented or performed with a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor.

Any connection may be properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Similarly, a list of at least one of A; B; or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on. Further, as used herein, including in the claims, a “set” may include one or more elements.

The terms “transmitting,” “receiving,” or “communicating,” when referring to a network entity, may refer to any portion of a network entity (e.g., a base station, a CU, a DU, a RU) of a RAN communicating with another device (e.g., directly or via one or more other network entities).

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form to avoid obscuring the concepts of the described example.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus for wireless communication, comprising:
at least one memory; and
at least one processor coupled with the at least one memory and configured to cause the apparatus to:
factorize, based on Khatri-Rao factorization and upon satisfaction of a metric, at least one information vector into one or more components, wherein each component comprises a first factor vector and a second factor vector, and each of the first factor vector and the second factor vector has fewer elements than the information vector, and the at least one information vector has unit Euclidean length and includes a set of information parameters;
generate encoded information by encoding at least the first factor vector or the second factor vector in at least one of the one or more components; and
transmit a first signaling indicating the encoded information.

2. The apparatus of claim 1, wherein the first factor vector is a first column vector, the second factor vector is a second column vector, and the information vector is a column vector.

3. The apparatus of claim 1, wherein the set of information parameters are based on channel state information.

4. The apparatus of claim 1, wherein the at least one processor is further configured to cause the apparatus to:
receive at least one reference signal; and
generate channel state information based on the at least one reference signal.

5. The apparatus of claim 1, wherein the at least one processor is further configured to cause the apparatus to determine the information parameters of the set of information parameters are based on distinct attributes extracted by an artificial intelligence or machine learning model.

6. The apparatus of claim 1, wherein to transmit the first signaling, the at least one processor is configured to cause the apparatus to transmit the first signaling to a first device, and wherein the at least one processor is further configured to cause the apparatus to determine the information parameters of the set of information parameters based on signaling from a second device that is different than the first device.

7. The apparatus of claim 1, wherein to transmit the first signaling, the at least one processor is configured to cause the apparatus to transmit the first signaling to a first device, and wherein the at least one processor is further configured to cause the apparatus to map the information vector to obtain a real-valued information vector using a mapping that is a one-to-one mapping known at the first device.

8. The apparatus of claim 1, wherein to generate the encoded information, the at least one processor is configured to cause the apparatus to determine at least one quantized representation of at least the first factor vector or the second factor vector in at least one of the one or more components based on at least one of a scalar quantization or a vector quantization scheme.

9. The apparatus of claim 1, wherein to generate the encoded information, the at least one processor is configured to cause the apparatus to encode at least the first factor vector or the second factor vector in at least one of the one or more components in a form of at least one index corresponding to one or more codebooks.

10. The apparatus of claim 1, wherein to generate the encoded information, the at least one processor is configured to cause the apparatus to obtain a latent representation of at least the first factor vector or the second factor vector in at least one of the one or more components using an artificial intelligence or machine learning model.

11. The apparatus of claim 1, wherein to generate the encoded information, the at least one processor is configured to cause the apparatus to bit encode at least the first factor vector or the second factor vector in at least one of the one or more components.

12. The apparatus of claim 1, wherein the at least one processor is further configured to cause the apparatus to:
factorize, based on Khatri-Rao factorization, the first factor vector into one or more additional components that each include a third factor vector and a fourth factor vector; and
generate the encoded information by encoding at least the third factor vector or the fourth factor vector in at least one of the one or more additional components.

13. The apparatus of claim 1, wherein the at least one processor is further configured to cause the apparatus to:
determine an error vector indicating an error between the at least one information vector and a Khatri-Rao product of the first factor vector and the second factor vector;
select a particular number of largest elements of the error vector; and
include, in the first signaling, an indication of both the particular number of largest elements of the error vector and positions of the particular number of largest elements in the error vector.

14. The apparatus of claim 1, wherein the metric is cosine similarity or cosine distance.

15. An apparatus for wireless communication, comprising:
at least one memory; and
at least one processor coupled with the at least one memory and configured to cause the apparatus to:
receive a set of information and a set of parameters, wherein the set of information comprises at least one set of components wherein each component includes an encoded first factor vector and an encoded second factor vector and wherein each set of components corresponds to an information vector;
decode the encoded first factor vector and the encoded second factor vector;
generate a Khatri-Rao product of the first factor vector and the second factor vector corresponding to each of the components; and
reconstruct an information vector by adding the Khatri-Rao products corresponding to each of the components.

16. A method performed by an apparatus, the method comprising:
factorizing, based on Khatri-Rao factorization and upon satisfaction of a metric, at least one information vector into one or more components, wherein each component comprises a first factor vector and a second factor vector, and each of the first factor vector and the second factor vector has fewer elements than the information vector, and the at least one information vector has unit Euclidean length and includes a set of information parameters;
generating encoded information by encoding at least the first factor vector or the second factor vector in at least one of the components; and
transmitting the encoded information.

17-20. (canceled)

21. The method of claim 16, wherein the metric is cosine similarity or cosine distance.

22. A method performed by an apparatus, the method comprising:
receiving a set of information and a set of parameters, wherein the set of information comprises at least one set of components wherein each component includes an encoded first factor vector and an encoded second factor vector and wherein each set of components corresponds to an information vector;
decoding the encoded first factor vector and the encoded second factor vector;
generating a Khatri-Rao product of the first factor vector and the second factor vector corresponding to each of the components; and
reconstructing an information vector by adding the Khatri-Rao products corresponding to each of the components.

23. The method of claim 22, wherein the set of parameters comprises one or more of information indicating a number of components of at least one set of components, or dimensions of the encoded first and second factor vectors in each component of at least one set of components.

24. The apparatus of claim 15, wherein the set of parameters comprises one or more of information indicating a number of components of at least one set of components, or dimensions of the encoded first and second factor vectors in each component of at least one set of components.
